(19) United States
(12) Patent Application Publication
(10) Pub. No.: US 2026/0163362 A1
(43) Pub. Date: Jun. 11, 2026

(54) SYSTEMS, METHODS, APPARATUS, AND ARTICLES OF MANUFACTURE TO PROTECT CIRCUITS DURING AVALANCHE CURRENT

(71) Applicant: TEXAS INSTRUMENTS INCORPORATED, Dallas, TX (US)

(72) Inventors: Adam Holmes Kinsel, Dallas, TX (US); Francisco Lauzurique, New Caney, TX (US); Masahiro Yoshioka, Plano, TX (US)

(21) Appl. No.: 19/255,129

(22) Filed: Jun. 30, 2025

Related U.S. Application Data
(60) Provisional application No. 63/730,628, filed on Dec. 11, 2024.

(51) Int. Cl. H02H 9/00; B60L 3/00; G01R 31/14; H02H 7/18; H02H 9/02

(52) U.S. Cl. CPC H02H 9/005; B60L 3/0046; G01R 31/14; H02H 7/18; H02H 9/02

(57) ABSTRACT

An example apparatus includes a first transistor having a control terminal, a first terminal adapted to be coupled to a first resistor, and a second terminal adapted to be coupled to a second resistor. The apparatus includes a second transistor having a control terminal, a first terminal, and a second terminal, the control terminal adapted to be coupled to a ground terminal, the first terminal coupled to the first terminal of the first transistor. The apparatus includes a driver having a supply terminal, an input, and an output, the supply terminal coupled to the second terminal of the second transistor, the output coupled to the control terminal of the first transistor. The apparatus includes a temperature-based control circuit having a supply terminal coupled to the second terminal of the second transistor and an output coupled to the input of the driver, the temperature-based control circuit capable of: monitoring a temperature sensor to determine a measured temperature indicative of a temperature of the first transistor; responsive to the measured temperature being greater than or equal to a fault threshold, providing a first signal to the driver, the driver to control the first transistor responsive to the first signal; responsive to the measured temperature being less than a lower threshold, providing a second signal to the driver, the driver to control the first transistor responsive to the second signal; and responsive to the measured temperature being greater than or equal to an upper threshold, providing a third signal to the driver, the driver to control the first transistor responsive to the third signal, the upper threshold being less than the fault threshold.

### CROSS-REFERENCE TO RELATED APPLICATION

This patent application claims the benefit of and priority to U.S. Provisional Patent Application No. 63/730,628 filed Dec. 11, 2024, which is hereby incorporated herein by reference in its entirety.

### TECHNICAL FIELD

This description relates generally to circuit protection and, more particularly, to systems, methods, apparatus, and articles of manufacture to protect circuits during avalanche current.

### BACKGROUND

In electrical systems, circuit protection is crucial for providing safety and reliability by preventing damage from overcurrent, overvoltage, short circuits, and other faults. Common types of circuit protection include fuses, circuit breakers, metal-oxide varistors (MOVs), transient voltage suppressor (TVS) diodes, and thermal protection devices. Also, electronic protection circuits, such as crowbar circuits and current limiters, are often integrated into power systems to offer more precise and reusable protection techniques. Each type of circuit protection serves a critical role depending on the application and target response time, durability, and cost for the application.

### SUMMARY

For systems, methods, apparatus, and articles of manufacture to protect circuits during avalanche current, an example apparatus includes a first transistor having a control terminal, a first terminal adapted to be coupled to a first resistor, and a second terminal adapted to be coupled to a second resistor. The apparatus includes a second transistor having a control terminal, a first terminal, and a second terminal, the control terminal adapted to be coupled to a ground terminal, the first terminal coupled to the first terminal of the first transistor. The apparatus includes a driver having a supply terminal, an input, and an output, the supply terminal coupled to the second terminal of the second transistor, the output coupled to the control terminal of the first transistor. The apparatus includes a temperature-based control circuit having a supply terminal coupled to the second terminal of the second transistor and an output coupled to the input of the driver, the temperature-based control circuit capable of: monitoring a temperature sensor to determine a measured temperature indicative of a temperature of the first transistor; responsive to the measured temperature being greater than or equal to a fault threshold, providing a first signal to the driver, the driver to control the first transistor responsive to the first signal; responsive to the measured temperature being less than a lower threshold, providing a second signal to the driver, the driver to control the first transistor responsive to the second signal; and responsive to the measured temperature being greater than or equal to an upper threshold, providing a third signal to the driver, the driver to control the first transistor responsive to the third signal, the upper threshold being less than the fault threshold. Other examples are described.

For systems, methods, apparatus, and articles of manufacture to protect circuits during avalanche current, an example method includes determining, with a temperature-based control circuit, a measured temperature indicative of a temperature of a transistor. The method includes responsive to the measured temperature being greater than or equal to a fault threshold, providing, with the temperature-based control circuit, a first signal to a driver, the driver to control the transistor responsive to the first signal. The method includes responsive to the measured temperature being less than a lower threshold, providing, with the temperature-based control circuit, a second signal to the driver, the driver to control the transistor responsive to the second signal. The method includes responsive to the measured temperature being greater than or equal to an upper threshold, providing, with the temperature-based control circuit, a third signal to the driver, the driver to control the transistor responsive to the third signal, the upper threshold being less than the fault threshold. Other examples are described.

For systems, methods, apparatus, and articles of manufacture to protect circuits during avalanche current, an example non-transitory computer-readable medium including instructions that cause at least one programmable circuit to monitor a temperature sensor to determine a measured temperature indicative of a temperature of a transistor. The instructions cause one or more of the at least one programmable circuit to, responsive to the measured temperature being greater than or equal to a fault threshold, provide a first signal to a driver, the driver to control the transistor responsive to the first signal. The instructions cause one or more of the at least one programmable circuit to, responsive to the measured temperature being less than a lower threshold, provide a second signal to the driver, the driver to control the transistor responsive to the second signal. The instructions cause one or more of the at least one programmable circuit to, responsive to the measured temperature being greater than or equal to an upper threshold, provide a third signal to the driver, the driver to control the transistor responsive to the third signal, the upper threshold being less than the fault threshold. Other examples are described.

### BRIEF DESCRIPTION OF THE DRAWINGS

FIG. 1 is a block diagram of an example system that includes an example insulation monitoring circuit (IMC) to monitor an isolation barrier between an example voltage source and an example chassis ground terminal.

FIG. 2 is a schematic diagram of an example implementation of the switch circuit of FIG. 1.

FIG. 3 is a schematic diagram of an example implementation of the temperature-based control circuit of FIG. 2.

FIG. 4 is an example state diagram representative of example operations of the switch circuit of FIGS. 1 and 2.

FIG. 5 is a graphical illustration of an example timing diagram representative of the operation of the switch circuit of FIGS. 1 and 2.

FIG. 6 is a flowchart representative of at least one of example machine-readable instructions or example operations that may be at least one of executed, instantiated, or performed by programmable circuitry to implement the temperature-based control circuit of FIGS. 2 and 3.

FIG. 7 is a block diagram of an example processing platform including programmable circuitry structured to execute, instantiate, or perform the example machine-readable instructions or perform the example operations of FIG. 6 to implement the temperature-based control circuit of FIGS. 2 and 3.

The drawings are not necessarily to scale. Generally, the same reference numbers in the drawing(s) and this description refer to the same or similar (in terms of at least one of functional or structural) features or parts. Although the drawings show regions with clean lines and boundaries, some or all of these lines and boundaries may be idealized. In reality, the boundaries or lines may be unobservable, blended or irregular.

### DETAILED DESCRIPTION

In power electronics applications such as electric vehicles (EVs) and hybrid EVs (HEVs), a high voltage power source, such as a high voltage battery pack, is isolated from the chassis of a vehicle to protect occupants (the driver, passengers, etc.) and to prevent damage to electrical components. Electrical systems in a vehicle monitor the integrity of isolation between a high voltage power source and the chassis to maintain safety in the vehicle throughout the lifetime of the vehicle. In general, such monitoring is referred to as insulation resistance monitoring (also referred to as isolation checking, insulation checking, isolation monitoring, insulation monitoring, and residual current monitoring (RCM)).

Insulation resistance monitoring is performed by measuring the resistance between each terminal of a high voltage power source and the chassis. Insulation resistance monitoring is performed throughout the lifetime of a vehicle to verify that the isolation from the high voltage power source of the vehicle is maintained. During an insulation monitoring test, an insulation monitoring circuit (IMC) checks an isolation resistance (R_{ISO}) by injecting a test signal into the isolation resistance and measuring a resulting leakage current. Based on the test signal and the leakage current, the IMC can compute the isolation resistance and determine whether the isolation resistance is within an acceptable range (for example, a range defined by a standard).

There are multiple architectures for an IMC. Some architectures employ a microcontroller that performs measurements via at least one isolated switch in a high voltage domain. Other architectures employ a microcontroller that performs measurements from a low voltage domain. Regardless of the architecture, an IMC can be used to monitor insulation resistance during the lifetime of a vehicle.

When implemented in a vehicle, an IMC is coupled across an isolation barrier of the vehicle, between (1) the chassis of the vehicle and (2) at least one the positive or negative terminal of a high voltage power source of the vehicle. As such, an IMC may be subjected to high voltages in real-world applications such as from faults, or substantial in-rush current. Also, before a vehicle is deployed (for example, during manufacturing of the vehicle) or during maintenance of the vehicle, the vehicle and the IMC may be tested to determine if an isolation barrier within the vehicle and the IMC can withstand high voltages (for example, resulting from faults, arcs, etc.). Such testing is referred to as high potential (Hi-Pot) testing. In some examples, an isolated switch that is to be implemented within an IMC can be subjected to Hi-Pot testing as a standalone component.

During a Hi-Pot test, a device under test (DUT) such as a vehicle, an IMC, or an isolated switch that is to be implemented in an IMC is subjected to three to five times the normal operating voltage for a given duration of time. For example, if the normal operating voltage of an EV or HEV is 1.2 kilovolts (kV), a Hi-Pot test may subject the isolation barrier of the EV or HEV, an IMC, or an isolated switch to a voltage between 3 kV and 5 kV. To pass a Hi-Pot test, an isolated component (for example, an isolation barrier in an EV or HEV, an IMC, an isolated switch to be implemented in an IMC, etc.) must withstand the applied Hi-Pot voltage for a given duration (for example, 60 seconds) without damaging the isolated component (for example, inducing leakage current, failing short, failing open, etc.). During a Hi-Pot test, an isolated switch (either implemented in an IMC or as a standalone component) enters a breakdown mode of operation in which the isolated switch conducts avalanche current set by a current limiting resistor (R_{LIM}). As a result of high power dissipation during the breakdown mode of operation, an isolated switch begins to heat.

To increase the amount of avalanche current an isolated switch can withstand, the amount of heat dissipated by the package of the isolated switch can be decreased. Some approaches to decrease heat dissipation include (1) increasing the resistance of a current limiting resistor and (2) adding a transient voltage suppressor (TVS) clamp in parallel with an isolated switch. Increasing the resistance of a current limiting resistor increases the amount of heat dissipated by the current limiting resistor as compared to an isolated switch. However, increasing the resistance of a current limiting resistor limits the accuracy that can be achieved during insulation resistance monitoring.

For example, the accuracy of insulation resistance monitoring can be improved when the resistance of a current limiting resistor is close to an isolation impedance of interest. Also, to mitigate the heat dissipated by an isolated switch, the physical size of a current limiting resistor is increased to facilitate increased heat dissipation by the current limiting resistor. However, increasing the physical size of a current limiting resistor increases the area consumption of the approach. Adding a TVS clamp in parallel with an isolated switch also dissipates power outside the package of the isolated switch. However, adding a TVS clamp adds an additional component that increases the area consumption and monetary cost of the approach.

Another approach is to use a junction field-effect transistor (JFET) to generate a supply current for a gate driver and a controller responsive to the Hi-Pot voltage. When the temperature of an isolated switch exceeds a first threshold, the controller triggers the gate driver to enable the isolated switch to reduce the voltage across the isolated switch thereby reducing the amount of power dissipated by the isolated switch which cools the isolated switch. When the temperature of the isolated switch falls below a second threshold, the controller disengages the gate driver to disable the isolated switch which increases the voltage across the isolated switch thereby increasing the amount of power dissipated by the isolated switch. As such, the isolated switch warms responsive to the increased voltage. This approach permits the physical size of a current limiting resistor to be reduced and permits the resistance of the current limiting resistor to be close to the isolation impedance of interest. As such, the area and cost of this approach can be reduced and the accuracy of insulation monitoring can be improved. However, this approach does not support enough avalanche current for modern applications.

For example, the goal of a modern Hi-Pot test in a vehicle may be to determine if high leakage current (as high as 3 milliamps (mA)) passes through an isolation barrier of the vehicle when a Hi-Pot voltage is applied. As described above, when an IMC is subjected to a Hi-Pot voltage, an isolated switch within the IMC may enter a breakdown mode of operation in which the isolated switch conducts avalanche current and heats. The amount of avalanche current that an isolated switch is capable of conducting depends on the amount of heat dissipated by the package of the isolated switch. Thus, if an isolated switch within an IMC heats to too large of a degree, then the isolated switch is not be able to conduct high leakage currents that may arise during modern Hi-Pot tests. As such, an IMC may not be able to detect high leakage current that may manifest in modern Hi-Pot testing.

To decrease the heat dissipated by an isolated switch while avoiding the disadvantages of the above-described approaches, examples described herein include a JFET to generate a supply current for a temperature-based controller responsive to the Hi-Pot voltage. The temperature-based controller utilizes four thresholds to manage temperature during the breakdown mode of operation. For example, a first upper threshold (also referred to as a fault threshold) that is sufficiently above the temperature during normal operating conditions of an isolated switch is used to trigger when the isolated switch is entering a fault condition such as a breakdown mode of operation. After the temperature of the isolated switch satisfies the first upper threshold, the isolated switch enters the fault state, and the temperature-based controller triggers a gate driver to enable the isolated switch to reduce the voltage across the isolated switch thereby reducing the amount of power dissipated by the isolated switch which cools the isolated switch.

In examples described herein, when the fault state is set, the temperature-based controller utilizes a second upper threshold, a first lower threshold, and a second lower threshold (also referred to as a cleared fault threshold). When the temperature of the isolated switch falls below the first lower threshold, the temperature-based controller disengages the gate driver to disable the isolated switch which increases the voltage across the isolated switch and allows the isolated switch to conduct avalanche current thereby increasing the amount of power dissipated by the isolated switch. As such, the isolated switch warms responsive to the increased voltage. When the temperature of the isolated switch exceeds the second upper threshold, the temperature-based controller triggers the gate driver to enable the isolated switch to reduce the voltage across the isolated switch thereby reducing the amount of power dissipated by the isolated switch which cools the isolated switch.

In examples described herein, when the temperature of the isolated switch falls below the second lower threshold, the temperature-based controller clears the fault state. For example, when the isolated switch has cooled sufficiently, the temperature-based controller clears the fault state and the isolated switch can return to normal operation. When the fault state is cleared, the temperature-based controller utilizes the first upper threshold to regulate temperature of the isolated switch. In examples described herein, by setting the first upper threshold to be sufficiently above the temperature during normal operating conditions of an isolated switch, described systems, methods, apparatus, and articles of manufacture avoid triggering the fault state during normal operating conditions. Also, by setting the second upper threshold to be below the first upper threshold, examples described herein maintain a lower average junction temperature than other approaches. In this manner, devices implementing examples described herein can conduct more avalanche current as compared to other approaches.

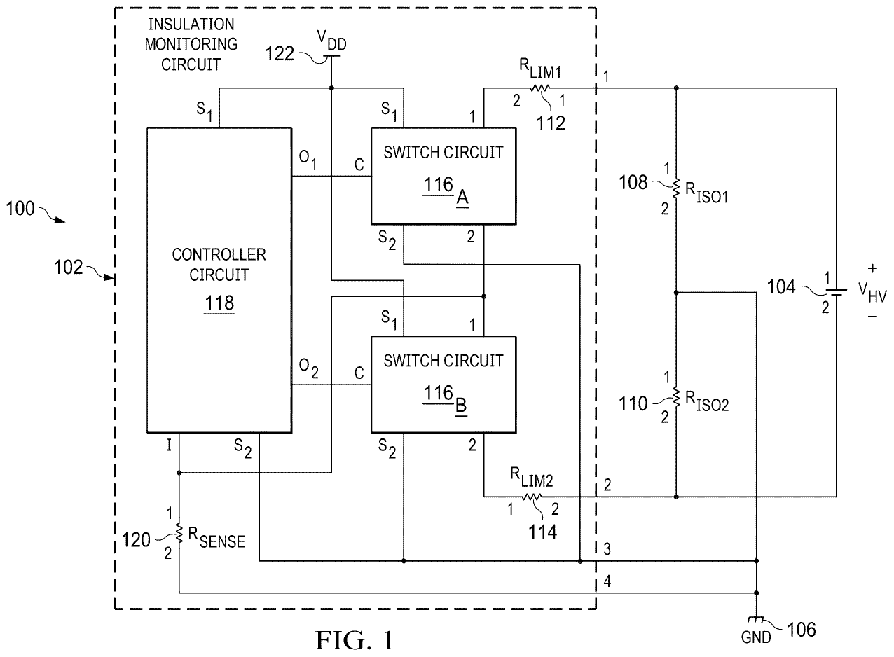

FIG. 1 is a block diagram of an example system 100 that includes an example insulation monitoring circuit (IMC) 102 to monitor an isolation barrier between an example voltage source 104 and an example chassis ground terminal 106. In the example of FIG. 1, the isolation barrier is represented by a first example isolation resistor 108 and a second example isolation resistor 110. Also, in the example of FIG. 1, the IMC 102 includes a first example current limiting resistor 112, a second example current limiting resistor 114, a first example switch circuit 116_{A}, a second example switch circuit 116_{B}, an example controller circuit 118, an example sensing resistor 120, and an example supply terminal 122.

In the example of FIG. 1, the system 100 is a vehicle such as an EV or HEV. As described above, the isolation resistor 108 and the isolation resistor 110 represent the isolation barrier between the voltage source 104 and the chassis ground terminal 106. For example, the voltage source 104 is the battery back of the vehicle and the chassis ground terminal 106 is the chassis of the vehicle. In the example of FIG. 1, the IMC 102 monitors the isolation barrier within the vehicle to maintain isolation between the voltage source 104 and the chassis ground terminal 106. In additional or alternative examples, the system 100 is any other type of system. For example, the system 100 may be a power train system, a battery management system, an energy storage system, a solar energy onboard charger, or an electric vehicle charging system.

In the example of FIG. 1, the vehicle represented by the system 100 may be subject to a Hi-Pot test to determine whether the isolation barrier is maintained even during high voltage conditions. During a Hi-Pot test, at least one of the switch circuit 116_{A} or the switch circuit 116 is subjected to a much higher voltage than during normal operating conditions and enters a breakdown mode of operation during which the at least one of the switch circuit 116_{A} or the switch circuit 116_{B} conducts avalanche current. In some examples, the IMC 102 may be subjected to a Hi-Pot test before being implemented within a vehicle. In such examples, the isolation resistor 108 and the isolation resistor 110 are omitted and the voltage source 104 represents the Hi-Pot voltage source used to conduct the Hi-Pot test (for example, at a test bench).

Also or alternatively, at least one of the switch circuit 116_{A} or the switch circuit 116_{B} may be subjected to a Hi-Pot test as a standalone component. In such examples, most of the components of the system 100 are omitted and the voltage source 104 is coupled across the switch circuit 116_{A} or the switch circuit 116p and represents the Hi-Pot voltage source used to conduct the Hi-Pot test (for example, at a test bench). For example, the switch circuit 116_{A} or the switch circuit 116_{B} is added to a test board that includes a current limiting resistor (for example, one of the current limiting resistor 112 or the current limiting resistor 114) and a Hi-Pot voltage source (for example, the voltage source 104).

In the example of FIG. 1, the IMC 102 has a first terminal, a second terminal, a third terminal, and a fourth terminal. In the example of FIG. 1, each of the voltage source 104, the isolation resistor 108, the isolation resistor 110, the current limiting resistor 112, the current limiting resistor 114, and the sensing resistor 120 has a first terminal and a second terminal. Also, each of the switch circuit 116_{A} and the switch circuit 116p has a control terminal, a first supply terminal, a second supply terminal, a first terminal, and a second terminal. In the example of FIG. 1, the controller circuit 118 has a first supply terminal, a second supply terminal, an input, a first output, and a second output.

In the example of FIG. 1, the first terminal of the voltage source 104 is coupled to first terminal of the isolation resistor 108 and the first terminal of the current limiting resistor 112. For example, the first terminal of the current limiting resistor 112 is to operate as the first terminal of the IMC 102. In the example of FIG. 1, the second terminal of the voltage source 104 is coupled to the second terminal of the isolation resistor 110 and the second terminal of the current limiting resistor 114. For example, the second terminal of the current limiting resistor 114 is to operate as the second terminal of the IMC 102.

In the example of FIG. 1, the voltage source 104 provides an output voltage, shown as V_{HV}, such as the battery voltage of a vehicle. In additional or alternative examples, the voltage source 104 is a Hi-Pot voltage source for testing the IMC 102. As described above, in such examples, the isolation resistor 108 and the isolation resistor 110 are omitted. In some examples, the voltage source 104 is a Hi-Pot voltage source for testing at least one of the switch circuit 116_{A} or the switch circuit 116_{B}. As described above, in such examples, most of the components of the system 100 are omitted except for a current limiting resistor and a voltage source.

In the example of FIG. 1, the chassis ground terminal 106 is coupled to the second terminal of the isolation resistor 108, the first terminal of the isolation resistor 110, the second supply terminal of the switch circuit 116_{A}, the second supply terminal of the switch circuit 116_{B}, the second supply terminal of the controller circuit 118, and the second terminal of the sensing resistor 120. For example, the second supply terminal of the switch circuit 116_{A}, the second supply terminal of the switch circuit 116_{B}, and the second supply terminal of the controller circuit 118 are to operate as the third terminal of the IMC 102. Also, for example, the second terminal of the sensing resistor 120 is to operate as the fourth terminal of the IMC 102.

In the example of FIG. 1, the chassis ground terminal 106 is an electrical ground that connects the circuitry of a device or vehicle to the metal frame or chassis of the device or vehicle. In the example of FIG. 1, the chassis ground terminal 106 serves as a common grounding point in the system 100. As such, wiring in the system 100 (for example, a vehicle) can be simplified. In additional or alternative examples, the chassis ground terminal 106 is implemented by any other type of ground terminal.

In the example of FIG. 1, the first terminal of the isolation resistor 108 is coupled to the first terminal of the voltage source 104 and the first terminal of the current limiting resistor 112. Also, the second terminal of the isolation resistor 108 is coupled to the chassis ground terminal 106. The example isolation resistor 108 of FIG. 1 has a resistance of R_{ISO1} which represents the isolation between the first terminal (also referred to as the positive terminal) of the voltage source 104 and the chassis ground terminal 106. For example, the resistance (R_{ISO1}) of the isolation resistor 108 is on the order of kiloohms (kΩ) or megaohms (MΩ) (for example, between 350 kΩ and 30 MΩ).

In the example of FIG. 1, the first terminal of the isolation resistor 110 is coupled to the chassis ground terminal 106. Also, the second terminal of the isolation resistor 110 is coupled to the second terminal of the voltage source 104 and the second terminal of the current limiting resistor 114. The example isolation resistor 110 of FIG. 1 has a resistance of R_{ISO2} which represents the isolation between the second terminal (also referred to as the negative terminal) of the voltage source 104 and the chassis ground terminal 106. For example, the resistance (R_{ISO2}) of the isolation resistor 110 is on the order of kΩ or MΩ (for example, between 350Ω and 30 MΩ).

In the example of FIG. 1, the first terminal of the current limiting resistor 112 is coupled to the first terminal of the voltage source 104 and the first terminal of the isolation resistor 108. Also, the second terminal of the current limiting resistor 112 is coupled to the first terminal of the switch circuit 116_{A}. The example current limiting resistor 112 of FIG. 1 has a resistance of R_{LIM1} Which is approximately the same as the resistance (R_{ISO1}) of the isolation resistor 108. In the example of FIG. 1, the first terminal of the current limiting resistor 114 is coupled to the second terminal of the switch circuit 116_{B}. Also, the second terminal of the current limiting resistor 114 is coupled to the second terminal of the voltage source 104 and the second terminal of the isolation resistor 110. The example current limiting resistor 114 of FIG. 1 has a resistance of R_{LIM2} which is approximately the same as the resistance (R_{ISO2}) of the isolation resistor 110.

In the example of FIG. 1, the control terminal of the switch circuit 116_{A} is coupled to the first output of the controller circuit 118. In the example of FIG. 1, the first supply terminal of the switch circuit 116_{A} is coupled to the supply terminal 122 and the second supply terminal of the switch circuit 116_{A} is coupled to the chassis ground terminal 106. Also, in the example of FIG. 1, the first terminal of the switch circuit 116_{A} is coupled to the second terminal of the current limiting resistor 112 and the second terminal of the switch circuit 116_{A} is coupled to the first terminal of the switch circuit 116_{B}, the input of the controller circuit 118, and the first terminal of the sensing resistor 120. In the example of FIG. 1, the switch circuit 116_{A} is an isolated solid-state relay designed for high voltage automotive and industrial applications.

In the example of FIG. 1, the control terminal of the switch circuit 116_{B} is coupled to the second output of the controller circuit 118. In the example of FIG. 1, the first supply terminal of the switch circuit 116_{B} is coupled to the supply terminal 122 and the second supply terminal of the switch circuit 116_{B} is coupled to the chassis ground terminal 106. Also, in the example of FIG. 1, the first terminal of the switch circuit 116_{B} is coupled to the second terminal of the switch circuit 116_{A}, the input of the controller circuit 118, and the first terminal of the sensing resistor 120 and the second terminal of the switch circuit 116_{B} is coupled to the first terminal of the current limiting resistor 114. In the example of FIG. 1, the switch circuit 116_{B} is an isolated solid-state relay designed for high voltage automotive and industrial applications.

In the example of FIG. 1, each of the switch circuit 116_{A} and the switch circuit 116_{B} includes one or more transistors coupled between respective first terminals and second terminals of the switch circuit 116_{A} and the switch circuit 116_{B}. The one or more transistors of the switch circuit 116_{A} and the switch circuit 116_{B} can be implemented as one or more metal-oxide semiconductor field-effect transistors (MOSFETs), one or more bipolar junction transistors (BJTs), one or more JFETs, one or more insulated-gate bipolar transistors (IGBTs), or other types of transistors. In the example of FIG. 1, each of the switch circuit 116_{A} and the switch circuit 116_{B} includes back-to-back power MOSFETs where respective power MOSFETs include a body diode coupled between the source and drain terminals of the respective power MOSFETs. When a reverse bias voltage is applied between drain and source of a MOSFET, an electric field is set up across the positive-negative (P-N) junction of a body diode of the MOSFET.

When the applied voltage increases beyond a breakdown voltage, a critical field is reached where the P-N junction can no longer support the applied voltage. The increased voltage results in avalanche breakdown in which reverse current flows through the body diode. For example, responsive to applying a Hi-Pot voltage V_{HV} across the first terminal and the second terminal of the IMC 102, avalanche breakdown can occur across the P-N junction(s) of the body diode(s) of the one or more power MOSFETs of at least one of the switch circuit 116_{A} or the switch circuit 116_{B} to provide for avalanche current flow through the at least one of the switch circuit 116_{A} or the switch circuit 116_{B}.

As used herein, the term avalanche condition refers to an electrical breakdown of an insulating region of a switch (for example, a P-N junction of a semiconductor power device) responsive to an applied electric field. For example, application of a sufficiently high voltage or current to the first terminal and the second terminal of the IMC 102 while at least one of the switch circuit 116_{A} or the switch circuit 116_{B} is disabled (for example, not conducting), such as during a Hi-Pot test, can create an electric field across an insulating region of the one or more power MOSFETs of the at least one of the switch circuit 116_{A} or the switch circuit 116_{B} sufficient to trigger electrical breakdown. Avalanche current, thus, can flow through the at least one of the switch circuit 116_{A} or the switch circuit 116_{B} responsive to the electrical breakdown.

In the example of FIG. 1, the first supply terminal of the controller circuit 118 is coupled to the supply terminal 122 and the second supply terminal of the controller circuit 118 is coupled to the chassis ground terminal 106. Also, the input of the controller circuit 118 is coupled to the second terminal of the switch circuit 116_{A}, the first terminal of the switch circuit 116_{B}, and the first terminal of the sensing resistor 120. In the example of FIG. 1, the first output of the controller circuit 118 is coupled to the control terminal of the switch circuit 116_{A} and the second output of the controller circuit 118 is coupled to the control terminal of the switch circuit 116_{B}. In the example of FIG. 1, the controller circuit 118 is a microcontroller unit (MCU). Thus, for example, the input of the controller circuit 118 is an analog-to-digital converter (ADC) input of the controller circuit 118, the first output of the controller circuit 118 is a first general purpose input/output (GPIO) of the controller circuit 118, and the second output of the controller circuit 118 is a second GPIO of the controller circuit 118.

In the example of FIG. 1, the controller circuit 118 implements a “turn-on” control loop to regulate operation of the switch circuit 116_{A} and the switch circuit 116_{B}. For example, the controller circuit 118 implements the “turn-on” control loop during insulation monitoring. For example, the controller circuit 118 provides control signals as pulses having a duty cycle. The duty cycle of the control signals can be fixed or can vary over time. In the example of FIG. 1, the duty cycle can be set to inject a test signal into the isolation resistor 108 and the isolation resistor 110. As such, the controller circuit 118 can measure leakage current through the isolation resistor 108 and the isolation resistor 110 via the sensing resistor 120.

In the example of FIG. 1, the first terminal of the sensing resistor 120 is coupled to the second terminal of the switch circuit 116_{A}, the first terminal of the switch circuit 116_{B}, and the input of the controller circuit 118 and the second terminal of the sensing resistor 120 is coupled to the chassis ground terminal 106. In the example of FIG. 1, the sensing resistor 120 has a resistance of RSENSE. For example, the resistance of the sensing resistor 120 is selected by a designer of the IMC 102 to bring a voltage or current representative of the sensed leakage current to an operating range of the controller circuit 118. In the example of FIG. 1, the supply terminal 122 is coupled to the first supply terminal of the switch circuit 116_{A}, the first supply terminal of the switch circuit 116_{B}, and the first supply terminal of the controller circuit 118. For example, the supply terminal 122 provides a supply voltage (V_{DD}) to the switch circuit 116_{A}, the switch circuit 116, and the controller circuit 118.

As described above, during a Hi-Pot test, at least one of the switch circuit 116_{A} or the switch circuit 116_{B} may be subjected to high-stress voltages that can induce avalanche current in the one or more power MOSFETs of the at least one of the switch circuit 116_{A} or the switch circuit 116_{B}. Such high-stress voltages tend to increase power dissipation by a power MOSFET, which can also increase the temperature of a die on or in which the power MOSFET is implemented. For example, the increase in die temperature can damage packaging of an IC within which the die is implemented, such as causing delamination. Advantageously, each of the switch circuit 116_{A} and the switch circuit 116_{B} includes a temperature-based controller that utilizes four thresholds to manage temperature during Hi-Pot testing.

For example, the temperature-based controller utilizes a first upper threshold (also referred to as a fault threshold) that is sufficiently above the temperature during normal operating conditions of the switch circuit 116_{A} and the switch circuit 116_{B} to trigger when the switch circuit 116_{A} or the switch circuit 116_{B} is entering a fault condition such as a breakdown mode of operation. After the temperature of the switch circuit 116_{A} or the switch circuit 116_{B} satisfies the first upper threshold, the switch circuit 116_{A} or the switch circuit 116_{B} enters the fault state, and the temperature-based controller triggers a gate driver to enable the switch circuit 116_{A} or the switch circuit 116_{B} to reduce the voltage across the switch circuit 116_{A} or the switch circuit 116_{B}. As such, the amount of power dissipated by the switch circuit 116_{A} or the switch circuit 116_{B} is reduced which cools the switch circuit 116_{A} or the switch circuit 116_{B}.

In the example of FIG. 1, when the fault state is set, the temperature-based controller utilizes a second upper threshold, a first lower threshold, and a second lower threshold (also referred to as a cleared fault threshold). When the temperature of the switch circuit 116_{A} or the switch circuit 116p falls below the first lower threshold, the temperature-based controller disengages the gate driver to disable the switch circuit 116_{A} or the switch circuit 116_{B} which increases the voltage across the switch circuit 116_{A} or the switch circuit 116_{B} and allows the switch circuit 116_{A} or the switch circuit 116_{B} to conduct avalanche current. As such, the amount of power dissipated by the switch circuit 116_{A} or the switch circuit 116p is increased which raises the temperature of the switch circuit 116_{A} or the switch circuit 116_{B}.

In the example of FIG. 1, when the temperature of the switch circuit 116_{A} or the switch circuit 116_{B} exceeds the second upper threshold, the temperature-based controller triggers the gate driver to enable the switch circuit 116_{A} or the switch circuit 116p to reduce the voltage across the switch circuit 116_{A} or the switch circuit 116_{B}. As such, the amount of power dissipated by the switch circuit 116_{A} or the switch circuit 116_{B} is reduced which cools the switch circuit 116_{A} or the switch circuit 116_{B}. In the example of FIG. 1, when the temperature of the switch circuit 116_{A} or the switch circuit 116p falls below the second lower threshold, the temperature-based controller clears the fault state. For example, when the switch circuit 116_{A} or the switch circuit 116_{B} has cooled sufficiently, the temperature-based controller clears the fault state and the switch circuit 116_{A} or the switch circuit 116p can return to normal operation. When the fault state is cleared, the temperature-based controller utilizes the first upper threshold to regulate temperature of the switch circuit 116_{A} or the switch circuit 116_{B}.

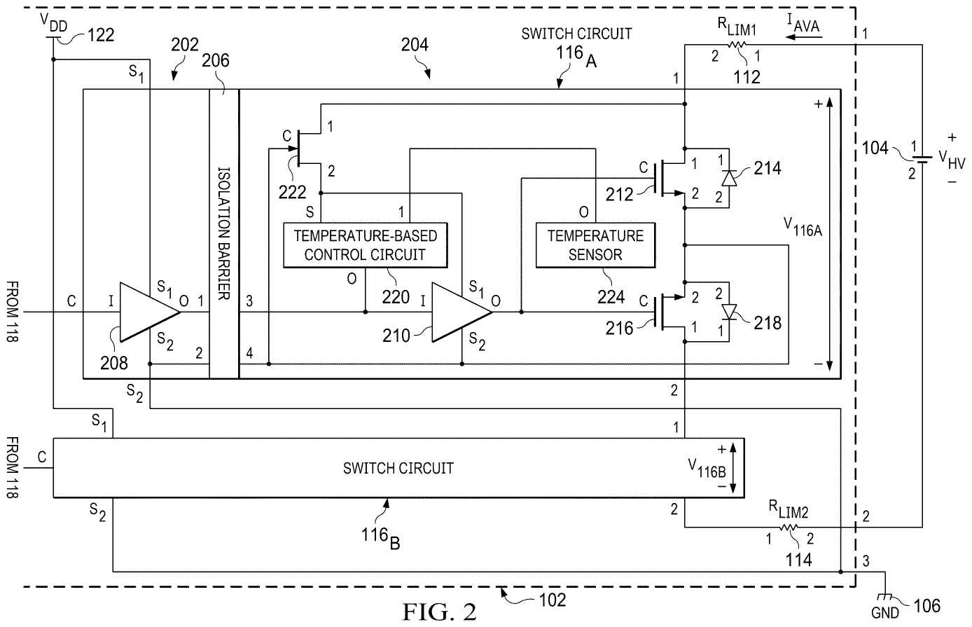

FIG. 2 is a schematic diagram of an example implementation of the switch circuit 116_{A} of FIG. 1. In the example of FIG. 2, the switch circuit 116_{B} is implemented similarly to the switch circuit 116_{A}. The example switch circuit 116_{A} includes an example low-voltage domain 202 and an example high-voltage domain 204 separated by an example isolation barrier 206. In the example of FIG. 2, the low-voltage domain 202 includes a first example driver 208 and the high-voltage domain 204 includes a second example driver 210 to drive a first example transistor 212 having a first example body diode 214 and a second example transistor 216 having a second example body diode 218.

In the example of FIG. 2, the high-voltage domain 204 also includes an example temperature-based control circuit 220 that is supplied via a third example transistor 222 and controls the transistor 212 and the transistor 216 via the driver 210 responsive to an example temperature sensor 224. In the example of FIG. 2, the switch circuit 116_{A} is implemented as an IC including two substrates. For example, the low-voltage domain 202 is implemented on a first substrate and the high-voltage domain 204 is implemented on a second substrate where the first substrate and the second substrate are implemented within IC packaging material. In the example of FIG. 2, the driver 208 is implemented on a first substrate and the driver 210, the transistor 212, the body diode 214, the transistor 216, the body diode 218, the temperature-based control circuit 220, the transistor 222, and the temperature sensor 224 are implemented on a second, common substrate (also referred to as a die).

In the example of FIG. 2, the isolation barrier 206 has a first terminal, a second terminal, a third terminal, and a fourth terminal. In the example of FIG. 2, each of the driver 208 and the driver 210 has a first supply terminal, a second supply terminal, an input, and an output. Also, each of the example transistor 212, the example transistor 216, and the example transistor 222 of FIG. 2 has a control terminal (a gate), a first terminal (a drain), and a second terminal (a source) and each of the example body diode 214 and the example body diode 218 of FIG. 2 has an effective or inherent first terminal (a cathode) and an effective or inherent second terminal (an anode). In the example of FIG. 2, the temperature-based control circuit 220 has a supply terminal, an input, and an output and the temperature sensor 224 has an output.

In the example of FIG. 2, circuitry of the low-voltage domain 202 operates at low voltages (for example, between 1.8 volts (V) and 15 V) and interfaces with control logic circuitry or microcontrollers such as the controller circuit 118. Also, in the example of FIG. 2, circuitry of the high-voltage domain 204 drives power devices such as the transistor 212 and the transistor 216 that operate at high voltages (for example, between 48 V and more than 600 V). In the example of FIG. 2, the isolation barrier 206 is implemented using components such as at least one of optocouplers, transformers, capacitors, or digital isolators. For example, the isolation barrier 206 prevents direct electrical connection between the low-voltage domain 202 and the high-voltage domain 204. The isolation barrier 206 of FIG. 2 transmits signals via an insulating medium such as an optical medium, magnetic medium, or capacitive medium, which provides signal integrity while protecting low-voltage circuits from high-voltage surges or faults.

In the example of FIG. 2, the first terminal of the isolation barrier 206 interfaces with the third terminal of the isolation barrier 206 and the second terminal of the isolation barrier 206 interfaces with the fourth terminal of the isolation barrier 206. In the example of FIG. 2, the first terminal of the isolation barrier 206 is coupled to the output of the driver 208 and the second terminal of the isolation barrier 206 is coupled to the chassis ground terminal 106. Also, in the example of FIG. 2, the third terminal of the isolation barrier 206 is coupled to the input of the driver 210 and the fourth terminal of the isolation barrier 206 is coupled to second supply terminal of the driver 210. The fourth terminal of the isolation barrier 206 is also coupled to the second terminal of the transistor 212, the second terminal of the body diode 214, the second terminal of the transistor 216, the second terminal of the body diode 218, and the control terminal of the transistor 222.

In the example of FIG. 2, the first supply terminal of the driver 208 is coupled to the supply terminal 122 and the second supply terminal of the driver 208 is coupled to the chassis ground terminal 106. For example, the first supply terminal of the driver 208 is to operate as the first supply terminal of the switch circuit 116_{A} and the second supply terminal of the driver 208 is to operate as the second supply terminal of the switch circuit 116_{A}. In the example of FIG. 2, the input of the driver 208 is coupled to the first output of the controller circuit 118 and the output of the driver 208 is coupled to the first terminal of the isolation barrier 206. For example, the input of the driver 208 is to operate as the control terminal of the switch circuit 116_{A}. In the example of FIG. 2, the driver 208 is implemented using transistors that boost, shape, or condition control signals from the control circuit 118 to provide control signals that meet the timing and voltage requirements of the isolation barrier 206. For example, the driver 208 drives the isolation barrier 206 to reliably communicate signals with sufficient integrity.

In the example of FIG. 2, the first supply terminal of the driver 210 is coupled to the second terminal of the transistor 222 and the second supply terminal of the driver 210 is coupled to the fourth terminal of the isolation barrier 206. For example, the second supply terminal of the driver 210 is coupled to the chassis ground terminal 106 via the isolation barrier 206. In the example of FIG. 2, the input of the driver 210 is coupled to the third terminal of the isolation barrier 206. For example, the input of the driver 210 is coupled to the output of the driver 208 via the isolation barrier 206. Also, in the example of FIG. 2, the output of the driver 210 is coupled to the control terminal of the transistor 212 and the control terminal of the transistor 216. In the example of FIG. 2, the driver 210 is implemented by a gate driver that uses transistors to amplify or switch control signals provided by the driver 208 or the temperature-based control circuit 220 to operate power devices (for example, the transistor 212 and the transistor 216). For example, the driver 210 is designed to match the electrical requirements of the transistor 212 and the transistor 216 and provides sufficient current and voltage while protecting control circuitry such as the temperature-based control circuit 220 from damage.

As described above, the first supply terminal of the driver 210 is coupled to the second terminal of the transistor 222. In the example of FIG. 2, the control terminal of the transistor 222 is coupled to the fourth terminal of the isolation barrier 206. For example, the control terminal of the driver 210 is coupled to the chassis ground terminal 106 via the isolation barrier 206. In the example of FIG. 2, the first terminal of the transistor 222 is coupled to the second terminal of the current limiting resistor 112 and the first terminal of the transistor 212. Also, the second terminal of the transistor 222 is coupled to the first supply terminal of the driver 210 and the supply terminal of the temperature-based control circuit 220.

In the example of FIG. 2, the transistor 222 is a negative-channel (N-channel) JFET that supplies an input voltage to operate the temperature-based control circuit 220 and the driver 210, such as responsive to a voltage potential is applied across the first terminal and the second terminal of the IMC 102. For example, when the gate of an N-channel JFET is grounded, the N-channel JFET provides (for example, operating in pinch-off) a low-voltage supply (for example, about 5-20 V) at the source of the N-channel JFET to run the driver 210 and the temperature-based control circuit 220. When the drain of an N-channel JFET is low, the N-channel JFET behaves (for example, operating in the triode region) like a switch to turn off the driver 210 and the temperature-based control circuit 220.

In the example of FIG. 2, the control terminal of the transistor 212 is coupled to the output of the driver 210 and the first terminal of the transistor 212 is coupled to the second terminal of the current limiting resistor 112, the first terminal of the body diode 214, and the first terminal of the transistor 222. For example, the first terminal of the transistor 212 is to operate as the first terminal of the switch circuit 116_{A}. In the example of FIG. 2, the second terminal of the transistor 212 is coupled to the fourth terminal of the isolation barrier 206, the second terminal of the body diode 214, the second terminal of the transistor 216, and the second terminal of the body diode 218. Also, in the example of FIG. 2, the transistor 212 is implemented by an N-channel power field-effect transistor (FET).

In the example of FIG. 2, the control terminal of the transistor 216 is coupled to the output of the driver 210 and the first terminal of the transistor 216 is coupled to the first terminal of the switch circuit 116_{B} and the first terminal of the body diode 218. For example, the first terminal of the transistor 216 is to operate as the second terminal of the switch circuit 116_{A}. In the example of FIG. 2, the second terminal of the transistor 216 is coupled to the fourth terminal of the isolation barrier 206, the second terminal of the transistor 212, the second terminal of the body diode 214, and the second terminal of the body diode 218. In the example of FIG. 2, the transistor 216 is implemented by an N-channel power FET.

In the example of FIG. 2, the transistor 212 and the transistor 216 are coupled in series between the first terminal and the second terminal of the switch circuit 116_{A}. In particular, the transistor 212 and the transistor 216 are shown in a common source configuration, in which the sources of each of the transistor 212 and the transistor 216 are coupled together. The common-source configuration is useful for providing bi-directional voltage blocking. In the example of FIG. 2, the drains of the transistor 212 and the transistor 216 are coupled to the second terminal of the current limiting resistor 112 and the first terminal of the switch circuit 116_{B}, respectively.

As described above, the transistor 212 and the transistor 216 include the body diode 214 and the body diode 218, respectively. In the example of FIG. 2, the first terminal of the body diode 214 is coupled to the first terminal of the transistor 212 and the second terminal of the body diode 214 is coupled to the second terminal of the transistor 212. Also, in the example of FIG. 2, the first terminal of the body diode 218 is coupled to the first terminal of the transistor 216 and the second terminal of the body diode 218 is coupled to the second terminal of the transistor 216. In the example of FIG. 2, the body diode 214 and the body diode 218 have semiconductor junctions to block reverse current flow from the drain to the source of the transistor 212 and the transistor 216, respectively.

In the example of FIG. 2, the supply terminal of the temperature-based control circuit 220 is coupled to the second terminal of the transistor 222, the input of the temperature-based control circuit 220 is coupled to the output of the temperature sensor 224, and the output of the temperature-based control circuit 220 is coupled to the input of the driver 210. In the example of FIG. 2, the temperature-based control circuit 220 is implemented by at least one or more amplifiers, one or more voltage sources, one or more switches, one or more logic gates, and one or more flip-flops. As described herein, the temperature-based control circuit 220 controls the temperature of at least one of the transistor 212 or the transistor 216 to prevent damage while permitting avalanche current during a Hi-Pot test.

As described above, the IMC 102 may be subjected to a Hi-Pot test. For example, the voltage source 104 provides an output voltage, shown as V_{HV}, across the first terminal and the second terminal of the IMC 102. During a Hi-Pot test, the transistor 212 and the transistor 216 are disabled (for example, not conducting). As such, at least one of the transistor 212 or the transistor 216 may experience breakdown and conduct avalanche current during a Hi-Pot test when the voltage across the switch circuit 116_{A} is at a breakdown level (for example, 1.4 kV). For example, responsive to a positive voltage V_{HV} across the first terminal and the second terminal of the IMC 102, avalanche breakdown can occur across the PN junction of the body diode 214 of the transistor 212 to provide for avalanche current flow through the channel of the transistor 212. Responsive to the positive voltage V_{HV} across the first terminal and the second terminal of the IMC 102, the body diode 218 is forward biased to conduct current through the transistor 216. Power is dissipated responsive to the avalanche condition, which results in an increase in temperature of the transistor 212. For example, Equation 1 illustrates the avalanche current through the current limiting resistor 112, the switch circuit 116_{A}, the switch circuit 116_{B}, and the current limiting resistor 114, and Equation 2 illustrates the power dissipated by the switch circuit 116_{A} during an avalanche event.

$${I}_{AVA} = \frac{{V}_{HV} - {V}_{{116}_{A}} - {V}_{116 B}}{{R}_{LIM 1} + {R}_{LIM 2}} \qquad ( Equation 1 )$$

$${P}_{{AVA}_{{116}_{A}}} = {V}_{{116}_{A}} * {I}_{AVA} \qquad ( Equation 2 )$$

Responsive to a negative voltage V_{HV} across the first terminal and the second terminal of the IMC 102, avalanche breakdown can occur across the PN junction of the body diode 218 of the transistor 216 to provide for avalanche current flow through the channel of the transistor 216. Responsive to the negative voltage V_{HV} across the first terminal and the second terminal of the IMC 102, the body diode 214 is forward biased to conduct current through the transistor 212. Power is dissipated responsive to the avalanche condition, which results in an increase in temperature of the transistor 216. In the example of FIG. 2, the temperature-based control circuit 220 regulates the temperature of at least one of the transistor 212 or the transistor 216 responsive to the sensed temperature monitored by the temperature sensor 224.

In the example of FIG. 2, the temperature sensor 224 is coupled to the transistor 212 and the transistor 216. For example, the coupling schematically shown in FIG. 2 includes a conductive coupling, such as at least one of electrically conductive or thermally conductive connections. Also, the output of the temperature sensor 224 is coupled to the input of the temperature-based control circuit 220. In the example of FIG. 2, the temperature sensor 224 is a thermal sensor, such as a BJT, that is arranged physically adjacent to the transistor 212 and the transistor 216. For example, the temperature sensor 224 provides a sensor signal to the temperature-based control circuit 220 where the sensor signal is indicative of a temperature of at least one of the transistor 212 or the transistor 216. For example, the temperature corresponds to a junction temperature of the at least one of the transistor 212 or the transistor 216.

In the example of FIG. 2, the temperature sensor 224 provides an indirect measurement of the temperature of the at least one of the transistor 212 or the transistor 216. In the example of FIG. 2, the temperature sensor 224 is positioned in proximity to the transistor 212 and the transistor 216 and measures the junction temperature of a die in/on which the at least one of the transistor 212 or the transistor 216 is implemented. In the example of FIG. 2, an indirect measurement can be used as a proxy to monitor the junction temperature of the at least one of the transistor 212 or the transistor 216 provided that the temperature-based control circuit 220 is structured to correlate the measured temperature to the junction temperature of the at least one of the transistor 212 or the transistor 216. For example, the temperature-based control circuit 220 correlates the measured temperature to the junction temperature of the at least one of the transistor 212 or the transistor 216 based on one or more temperature thresholds maintained by the temperature-based control circuit 220 as described herein. In some examples, the temperature sensor 224 provides a direct measurement of the temperature of the at least one of the transistor 212 or the transistor 216.

In the example of FIG. 2, the temperatures sensor 224 provides the sensor signal as a voltage or current indicative of the temperature of at least one of the transistor 212 or the transistor 216. In some examples, the temperature sensor 224 monitors an electrical characteristic (such as voltage, current, or power) of the transistor 212 and the transistor 216 and provides a sensor signal responsive to the measured electrical characteristic. For example, the temperature sensor 224 monitors a voltage or current indicative of the measured temperature and provides the monitored voltage or current to the temperature-based control circuit 220.

Responsive to the sensor signal from the temperature sensor 224, the temperature-based control circuit 220 can detect an avalanche condition of at least one of the transistor 212 or the transistor 216 such as a breakdown mode of operation. For example, an avalanche condition may manifest in at least one of the transistor 212 or the transistor 216 during Hi-Pot testing. As described above, an avalanche condition increases power dissipation by at least one of the transistor 212 or the transistor 216 which also increases the temperature of a die on or in which the transistor 212 and the transistor 216 are implemented. The increase in die temperature can damage packaging of an IC (for example, the switch circuit 116_{A}) within which the die is implemented, such as causing delamination, causing the switch circuit 116_{A} to fail short, or causing the switch circuit 116_{A} to fail open.

Advantageously, the temperature-based control circuit 220 utilizes four thresholds to manage temperature of at least one of the transistor 212 or the transistor 216. In the example of FIG. 2, the temperature-based control circuit 220 utilizes a fault threshold that is sufficiently above the temperature of the transistor 212 and the transistor 216 during normal operating conditions to trigger when at least one of the transistor 212 or the transistor 216 is experiencing a fault condition (such as a breakdown mode of operation or thermal fault). For example, the normal operating temperature of the transistor 212 and the transistor 216 ranges from −40 degrees Celsius (° C.) and 150° C. and the fault threshold is set to 170° C.

Responsive to the temperature of at least one of the transistor 212 or the transistor 216 satisfying (for example, being greater than or equal to) the fault threshold, the temperature-based control circuit 220 sets a fault state to indicate that at least one of the transistor 212 or the transistor 216 is in a breakdown mode of operation. For example, responsive to the temperature of at least one of the transistor 212 or the transistor 216 satisfying the fault threshold, the temperature-based control circuit 220 provides a first signal to the driver 210. Responsive to the first signal, the driver 210 enables the transistor 212 and the transistor 216. In examples described herein, a transistor is enabled when the control voltage of the transistor, such as the gate-to-source voltage (V_{GS}) of an N-channel transistor, is at a level to cause the transistor to conduct current. For example, a transistor is enabled when the transistor is in a linear mode of operation or a saturation mode of operation.

In the example of FIG. 2, by signaling the driver 210 to enable the transistor 212 and the transistor 216 when the monitored temperature provided by the temperature sensor 224 satisfies the fault threshold, the temperature-based control circuit 220 reduces the voltage across the switch circuit 116_{A}. For example, the temperature-based control circuit 220 reduces the voltage across the switch circuit 116_{A} from a breakdown level (for example, 1.4 kV) to a supply level (for example, 5 V) for the driver 210 and the temperature-based control circuit 220. Thus, the amount of power dissipated by at least one of the transistor 212 or the transistor 216 is reduced which cools the at least one of the transistor 212 or the transistor 216, or, more generally, the switch circuit 116_{A}.

In the example of FIG. 2, when the fault state is set, the temperature-based control circuit 220 utilizes an upper threshold, a lower threshold, and a cleared fault threshold to regulate the temperature of at least one of the transistor 212 or the transistor 216. For example, the upper threshold is 150° C., the lower threshold is 115° C., and the cleared fault threshold is 100° C. In the example of FIG. 2, responsive to the temperature of at least one of the transistor 212 or the transistor 216 not satisfying (for example, being less than or equal to) the lower threshold, the temperature-based control circuit 220 disengages the driver 210 to disable the transistor 212 and the transistor 216. For example, responsive to the temperature of at least one of the transistor 212 or the transistor 216 not satisfying the lower threshold, the temperature-based control circuit 220 provides a second signal to the driver 210. Responsive to the second signal, the driver 210 disables the transistor 212 and the transistor 216.

In examples described herein, a transistor is disabled when the control voltage of the transistor, such as the gate-to-source voltage (V_{GS}) of an N-channel transistor, is at a level that does not cause the transistor to conduct current. For example, a transistor is disabled when the transistor is in a cutoff mode of operation. In the example of FIG. 2, by signaling the driver 210 to disable the transistor 212 and the transistor 216 when the monitored temperature provided by the temperature sensor 224 does not satisfy the lower threshold, the temperature-based control circuit 220 increases the voltage across the switch circuit 116_{A}. For example, the temperature-based control circuit 220 increases the voltage across the switch circuit 116_{A} from a supply level (for example, 5 V) for the driver 210 and the temperature-based control circuit 220 to a breakdown level (for example, 1.4 kV). As such, at least one of the transistor 212 or the transistor 216 enters a breakdown mode of operation and conducts avalanche current. Thus, the amount of power dissipated by at least one of the transistor 212 or the transistor 216 is increased which raises the temperature of the at least one of the transistor 212 or the transistor 216, or, more generally, the switch circuit 116_{A}.

In the example of FIG. 2, responsive to the temperature of at least one of the transistor 212 or the transistor 216 satisfying (for example, being greater than or equal to) the upper threshold, the temperature-based control circuit 220 triggers the driver 210 to enable the transistor 212 and the transistor 216. For example, the temperature-based control circuit 220 provides a third signal to the driver 210. Responsive to the third signal, the driver 210 enables the transistor 212 and the transistor 216. In the example of FIG. 2, by signaling the driver 210 to enable the transistor 212 and the transistor 216 when the monitored temperature provided by the temperature sensor 224 satisfies the upper threshold, the temperature-based control circuit 220 reduces the voltage across the switch circuit 116_{A}. For example, the temperature-based control circuit 220 reduces the voltage across the switch circuit 116_{A} from a breakdown level (for example, 1.4 kV) to a supply level (for example, 5 V) for the driver 210 and the temperature-based control circuit 220. Thus, the amount of power dissipated by at least one of the transistor 212 or the transistor 216 is reduced which cools the at least one of the transistor 212 or the transistor 216, or, more generally, the switch circuit 116_{A}.

In the example of FIG. 2, responsive to the temperature of at least one of the transistor 212 or the transistor 216 not satisfying (for example, being less than or equal to) the cleared fault threshold, the temperature-based control circuit 220 clears the fault state. For example, responsive to the temperature of at least one of the transistor 212 or the transistor 216 not satisfying the cleared fault threshold, the temperature-based control circuit 220 clears the fault state. When the fault state is not present, the temperature-based control circuit 220 utilizes the fault threshold to regulate the temperature of at least one of the transistor 212 or the transistor 216. For example, the fault state is to prevent the temperature-based control circuit 220 from providing a signal to the driver 210 unless the measured temperature is greater than or equal to the fault threshold. In some examples, one or more of the fault threshold, the upper threshold, the lower threshold, or the cleared fault threshold is a tunable, programmable, or otherwise adjustable threshold.

As described above, the temperature-based control circuit 220 regulates the temperature of at least one of the transistor 212 or the transistor 216 to prevent damage while permitting avalanche current, for example, during a Hi-Pot test. For example, by setting the fault threshold (for example, 170° C.) to be sufficiently above the temperature during normal operating conditions (for example, 150° C.) of the transistor 212 and the transistor 216, the temperature-based control circuit 220 avoids triggering the fault state during normal operating conditions of the switch circuit 116_{A}. Also, by setting the upper threshold (for example, 150° C.) to be below the fault threshold (for example, 170° C.), the temperature-based control circuit 220 maintains a lower average junction temperature than other approaches. For example, the temperature-based control circuit 220 maintains an average temperature of 132.5° C. at the junction of at least one of the transistor 212 or the transistor 216 whereas other approaches maintain an average junction temperature of 152.5° C. In this manner, the switch circuit 116_{A} can conduct more avalanche current as compared to other approaches.

Furthermore, at least because the temperature of the switch circuit 116_{A} is efficiently managed by the temperature-based control circuit 220, the physical size of the current limiting resistor 112 and the current limiting resistor 114 can be reduced which decreases the area consumption and monetary cost of the switch circuit 116_{A} compared to other approaches. Also, at least because the temperature of the switch circuit 116_{A} is efficiently managed by the temperature-based control circuit 220, the current limiting resistor 112 and the current limiting resistor 114 can be closely matched to the isolation resistor 108 and the isolation resistor 110, respectively. As such, insulation resistance monitoring performed by the IMC 102 is improved. The temperature-based control circuit 220 also improves the settling time of the IMC 102. For example, settling time refers to the period after a device, such as an EV or HEV, is powered on or after a significant change occurs in the device, such as a heavy load, and before an IMC stabilizes and provides accurate insulation resistance monitoring.

In the example of FIG. 2, the transistor 212 and the transistor 216 are N-channel MOSFETs. Alternatively, the transistor 212 and the transistor 216 may be N-channel FETs, N-channel IGBTs, N-channel JFETs, negative-positive-negative (NPN) BJTs or, with slight modifications, P-channel equivalent devices. The transistor 212 and the transistor 216 may be depletion mode devices, drain-extended devices, enhancement mode devices, natural transistors or other type of device structure transistors. Furthermore, the transistor 212 and the transistor 216 may be implemented in/over a silicon (Si) substrate, a silicon carbide (SiC) substrate, a gallium nitride (GaN) substrate, or a gallium arsenide (GaAs) substrate.

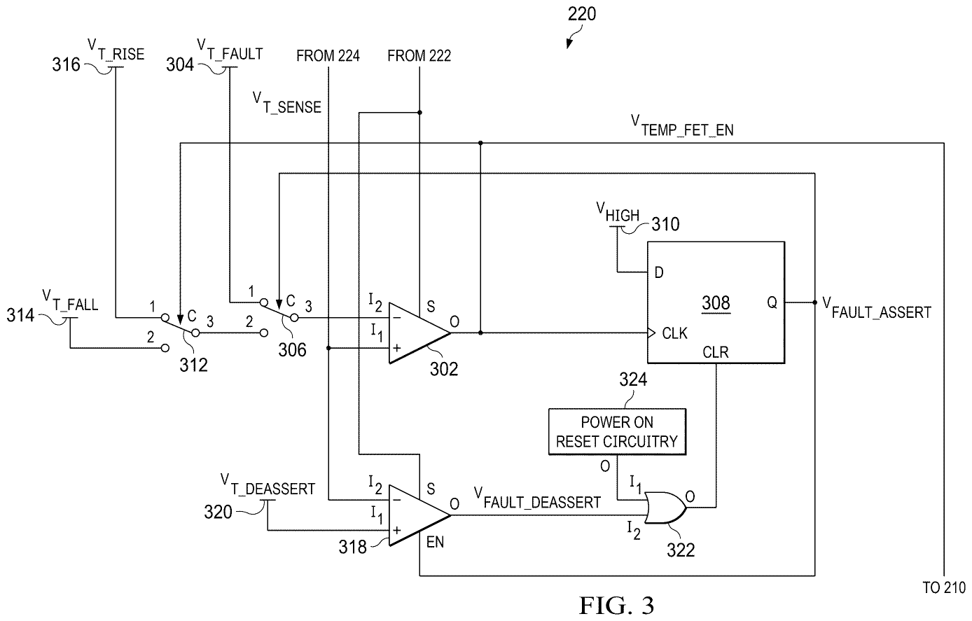

FIG. 3 is a schematic diagram of an example implementation of the temperature-based control circuit 220 of FIG. 2. In the example of FIG. 3, the temperature-based control circuit 220 includes a first example amplifier 302, an example fault threshold terminal 304, a first example switch 306, an example flip-flop 308, an example logic high terminal 310, a second example switch 312, an example lower threshold terminal 314, and an example upper threshold terminal 316. The example temperature-based control circuit 220 of FIG. 2 also includes a second example amplifier 318, an example cleared fault threshold terminal 320, an example OR gate 322, and example power on reset circuitry 324.

In the example of FIG. 3, each of the amplifier 302 and the amplifier 318 has a supply terminal, a first input, a second input, and an output. The example amplifier 318 of FIG. 3 also has an enable terminal. In the example of FIG. 3, each of the switch 306 and the switch 312 has a control terminal, a first terminal, a second terminal, and a third terminal. Also, the example flip-flop 308 of FIG. 3 has an input, a clock terminal, a clear terminal, and an output. In the example of FIG. 3, the OR gate 322 has a first input, a second input, and an output and the power on reset circuitry 324 has an output.

In the example of FIG. 3, the supply terminal of the amplifier 302 is coupled to the second terminal of the transistor 222, the first input of the amplifier 302 is coupled to the output of the temperature sensor 224, and the second input of the amplifier 302 is coupled to the third terminal of the switch 306. In the example of FIG. 3, the output of the amplifier 302 is coupled to the input of the driver 210, the clock terminal of the flip-flop 308, and the control terminal of the switch 312. The example amplifier 302 of FIG. 3 is implemented by an operational amplifier (op-amp) structured as a comparator.

In the example of FIG. 3, the amplifier 302 compares the voltage at the first input of the amplifier 302 to the voltage at the second input of the amplifier 302. Responsive to the voltage at the first input of the amplifier 302 being greater than or equal to the voltage at the second input of the amplifier 302, the amplifier 302 generates a logic high value (for example, a ‘1’, 5 V, etc.) at the output of the amplifier 302. Responsive to the voltage at the first input of the amplifier 302 being less than the voltage at the second input of the amplifier 302, the amplifier 302 generates a logic low value (for example, a ‘0’, 0 V, etc.) at the output of the amplifier 302.

In the example of FIG. 3, the fault threshold terminal 304 is coupled to the first terminal of the switch 306. In the example of FIG. 3, the fault threshold terminal 304 provides a voltage V_{T}_{_{FAULT}} representative of the fault threshold. For example, the voltage V_{T}_{_{FAULT}} provided at the fault threshold terminal 304 corresponds to a temperature of 170° C. As described above, the fault threshold is sufficiently above the temperature of the transistor 212 and the transistor 216 during normal operating conditions, which is 150° C. In the example of FIG. 3, the fault threshold terminal 304 may be implemented by the output of a linear regulator. In some examples, the fault threshold terminal 304 is implemented by an analog output of a microcontroller.

In the example of FIG. 3, the control terminal of the switch 306 is coupled to the output of the flip-flop 308, the first terminal of the switch 306 is coupled to the fault threshold terminal 304, the second terminal of the switch 306 is coupled to the third terminal of the switch 312, and the third terminal of the switch 306 is coupled to the second input of the amplifier 302. In the example of FIG. 3, the switch 306 is implemented by one or more transistors structured as a single pole, double throw (SPDT) or three-way switch. For example, the switch 306 can be toggled to couple the first terminal of the switch 306 to the third terminal of the switch 306 or to couple the second terminal of the switch 306 to the third terminal of the switch 306.

In the example of FIG. 3, the input of the flip-flop 308 is coupled to the logic high terminal 310, the clock terminal of the flip-flop 308 is coupled to the output of the amplifier 302, the clear terminal of the flip-flop 308 is coupled to the output of the OR gate 322, and the output of the flip-flop 308 is coupled to the control terminal of the switch 306 and the enable terminal of the amplifier 318. In the example of FIG. 3, the flip-flop 308 is implemented by a D flip-flop. For example, the flip-flop 308 captures a value of the input of the flip-flop 308 responsive to a rising edge of the signal at the clock terminal of the flip-flop 308 and holds the value at the output of the flip-flop 308 until the next rising edge of the signal at the clock terminal of the flip-flop 308. The example flip-flop 308 of FIG. 3 clears the value at the output of the flip-flop 308 to a logic low value (for example, a ‘0’, 0 V, etc.) responsive to a rising edge of the signal at the clear terminal of the flip-flop 308. In the example of FIG. 3, the signal provided by the flip-flop 308 is referred to as V_{FAULT_ASSERT}.

In some examples, the flip-flop 308 captures a value at the input of the flip-flop 308 responsive to a falling edge of the signal at the clock terminal of the flip-flop 308 and holds the value at the output of the flip-flop 308 until the next falling edge of the signal at the clock terminal of the flip-flop 308. In such examples, the first input of the amplifier 302 is coupled to the third terminal of the switch 306 and the second input of the amplifier 302 is coupled to the output of the temperature sensor 224. In some examples, the flip-flop 308 clears the value at the output of the flip-flop 308 to a logic low value (for example, a ‘0’, 0 V, etc.) responsive to a falling edge of the signal at the clear terminal of the flip-flop 308. In such examples, the OR gate 322 is implemented by a NOR gate.

In the example of FIG. 3, the logic high terminal 310 is coupled to the input of the flip-flop 308. In the example of FIG. 3, the logic high terminal 310 provides a voltage V_{HIGH} representative of a logic high value. For example, the voltage V_{HIGH} provided at the logic high terminal 310 is a ‘1’ or 5 V. In the example of FIG. 3, the logic high terminal 310 may be implemented by the output of a linear regulator. In some examples, the logic high terminal 310 is implemented by an analog output of a microcontroller.

In the example of FIG. 3, the control terminal of the switch 312 is coupled to the output of the amplifier 302, the first terminal of the switch 312 is coupled to the upper threshold terminal 316, the second terminal of the switch 312 is coupled to the lower threshold terminal 314, and the third terminal of the switch 312 is coupled to the second terminal of the switch 306. In the example of FIG. 3, the switch 312 is implemented by one or more transistors structured as an SPDT or three-way switch. For example, the switch 312 can be toggled to couple the first terminal of the switch 312 to the third terminal of the switch 312 or to couple the second terminal of the switch 312 to the third terminal of the switch 312.

In the example of FIG. 3, the lower threshold terminal 314 is coupled to the second terminal of the switch 312. In the example of FIG. 3, the lower threshold terminal 314 provides a voltage V_{T}_{_{FALL}} representative of the lower threshold. For example, the voltage V_{T}_{_{FALL}} provided at the lower threshold terminal 314 corresponds to a temperature of 115° C. As described above, the lower threshold of 115° C. is less than the upper threshold of 150° C. In the example of FIG. 3, the lower threshold terminal 314 may be implemented by the output of a linear regulator. In some examples, the lower threshold terminal 314 is implemented by an analog output of a microcontroller.

In the example of FIG. 3, the upper threshold terminal 316 is coupled to the first terminal of the switch 312. In the example of FIG. 3, the upper threshold terminal 316 provides a voltage V_{T}_{_{RISE}} representative of the upper threshold. For example, the voltage V_{T}_{_{RISE}} provided at the upper threshold terminal 316 corresponds to a temperature of 150° C. As described above, by setting the upper threshold to 150° C., which is below the fault threshold of 170° C. and above the lower threshold of 115° C., the temperature-based control circuit 220 maintains a lower average junction temperature than other approaches. In the example of FIG. 3, the upper threshold terminal 316 may be implemented by the output of a linear regulator. In some examples, the upper threshold terminal 316 is implemented by an analog output of a microcontroller.

In the example of FIG. 3, the supply terminal of the amplifier 318 is coupled to the second terminal of the transistor 222, the first input of the amplifier 318 is coupled to the cleared fault threshold terminal 320, the second input of the amplifier 318 is coupled to the output of the temperature sensor 224, the output of the amplifier 318 is coupled to the second input of the OR gate 322, and the enable terminal of the amplifier 318 is coupled to the output of the flip-flop 308. In the example of FIG. 3, the amplifier 318 is enabled responsive to a signal at the output of the flip-flop 308. For example, responsive to a logic high value (for example, a ‘1’, 5 V, etc.) at the output of the flip-flop 308, the amplifier 318 is enabled. Also, for example, responsive to a logic low value (for example, a ‘0’, 0 V, etc.) at the output of the flip-flop 308, the amplifier 318 is disabled.

In the example of FIG. 3, the amplifier 318 is implemented by an op-amp structured as a comparator. In the example of FIG. 3, when enabled, the amplifier 318 compares the voltage at the first input of the amplifier 318 to the voltage at the second input of the amplifier 318. Responsive to the voltage at the first input of the amplifier 318 being greater than or equal to the voltage at the second input of the amplifier 318, the amplifier 318 generates a logic high value (for example, a ‘1’, 5 V, etc.) at the output of the amplifier 318. Responsive to the voltage at the first input of the amplifier 318 being less than the voltage at the second input of the amplifier 318, the amplifier 318 generates a logic low value (for example, a ‘0’, 0 V, etc.) at the output of the amplifier 318. In the example of FIG. 3, the signal provided by the amplifier 318 is referred to as V_{FAULT_DEASSERT}.

In the example of FIG. 3, the cleared fault threshold terminal 320 is coupled to the first input of the amplifier 318. In the example of FIG. 3, the cleared fault threshold terminal 320 provides a voltage V_{T}_{_{DEASSERT}} representative of the cleared fault threshold. For example, the voltage VTD DEASSERT provided at the cleared fault threshold terminal 320 corresponds to a temperature of 100° C. In the example of FIG. 3, the cleared fault threshold terminal 320 may be implemented by the output of a linear regulator. In some examples, the cleared fault threshold terminal 320 is implemented by an analog output of a microcontroller.

In the example of FIG. 3, the first input of the OR gate 322 is coupled to the output of the power on reset circuitry 324, the second input of the OR gate 322 is coupled to the output of the amplifier 318, and the output of the OR gate 322 is coupled to the clear terminal of the flip-flop 308. In the example of FIG. 3, the OR gate 322 is implemented by one or more transistors. As described above, in some example the OR gate 322 is implemented as a NOR gate. In such examples, the flip-flop 308 is structured to clear the value at the output of the flip-flop 308 responsive to a falling edge at the output of the NOR gate.

In the example of FIG. 3, the output of the power on reset circuitry 324 is coupled to the first input of the OR gate 322. In the example of FIG. 3, the power on reset circuitry 324 is implemented by at least one of analog circuitry or digital circuitry. Also, in the example of FIG. 3, the power on reset circuitry 324 is structured to generate a logic high value (for example, a ‘1’, 5 V, etc.) when the switch circuit 116_{A} is reset or is powered on. Otherwise, the power on reset circuitry 324 is structured to generate a logic low value (for example, a ‘0’, 0 V, etc.). In this manner, the power on reset circuitry 324 resets the logic value held at the output of the flip-flop 308, via the OR gate 322, upon a reset or power on of the switch circuit 116_{A}.

In the example of FIG. 3, the temperature-based control circuit 220 controls the temperature of at least one of the transistor 212 or the transistor 216 to prevent damage while permitting avalanche current during a Hi-Pot test. For example, when the fault state is not set, the amplifier 302 compares the monitored temperature provided by the temperature sensor 224 to the fault threshold provided by the fault threshold terminal 304. For example, when the fault state is not set, the switch 306 is toggled to couple the first terminal of the switch 306 to the third terminal of the switch 306. In this manner, the fault state is to prevent the temperature-based control circuit 220 from providing a signal to the driver 210 unless the measured temperature provided by the temperature sensor 224 is greater than or equal to the fault threshold.

In the example of FIG. 3, responsive to the monitored temperature provided by the temperature sensor 224 being greater than or equal to the fault threshold provided by the fault threshold terminal 304, the amplifier 302 generates a logic high value. Responsive to a logic high value at the output of the amplifier 302, the driver 210 enables the transistor 212 and the transistor 216, allowing the transistor 212 and the transistor 216 to cool. In the example of FIG. 3, responsive to a logic high value at the output of the amplifier 302, the switch 312 toggles to couple the second terminal of the switch 312 to the third terminal of the switch 312.

In the example of FIG. 3, responsive to a logic high value at the output of the amplifier 302, the flip-flop 308 captures a logic high value provided by the logic high terminal 310 and holds the logic high value at the output of the flip-flop 308. In this manner, the flip-flop 308 sets a fault state. For example, the fault state indicates that at least one of the transistor 212 or the transistor 216 is in a breakdown mode of operation in which the at least one of the transistor 212 or the transistor 216 can conduct avalanche current and dissipate heat. In the example of FIG. 3, responsive to the logic high value at the output of the flip-flop 308, the switch 306 toggles to couple the second terminal of the switch 306 to the third terminal of the switch 306. Also, responsive to the logic high value at the output of the flip-flop 308, the amplifier 318 is enabled.

In the example of FIG. 3, responsive to the fault state being set, the amplifier 302 compares the monitored temperature provided by the temperature sensor 224 to the lower threshold provided by the lower threshold terminal 314. In the example of FIG. 3, responsive to the monitored temperature provided by the temperature sensor 224 being greater than or equal to the lower threshold provided by the lower threshold terminal 314, the amplifier 302 provides a logic high value. As such, after the fault state is initially set, the driver 210 continues to enable the transistor 212 and the transistor 216, allowing the transistor 212 and the transistor 216 to continue to cool.

In the example of FIG. 3, responsive to the fault state being set, the amplifier 318 compares the cleared fault threshold provided by the cleared fault threshold terminal 320 to the monitored temperature provided by the temperature sensor 224. In the example of FIG. 3, responsive to the cleared fault threshold provided by the cleared fault threshold terminal 320 being less than the monitored temperature provided by the temperature sensor 224, the amplifier 318 generates a logic low value. As such, the OR gate 322 provides a logic low value to the clear terminal of the flip-flop 308 and the flip-flop 308 maintains the fault state as set.

In the example of FIG. 3, responsive to the monitored temperature provided by the temperature sensor 224 being less than the lower threshold provided by the lower threshold terminal 314, the amplifier 302 generates a logic low value. Responsive to a logic low value at the output of the amplifier 302, the driver 210 disables the transistor 212 and the transistor 216, allowing the transistor 212 and the transistor 216 to return to a breakdown mode of operation if a voltage across the switch circuit 116_{A} is at a breakdown level. Also, responsive to a logic low value at the output of the amplifier 302, the switch 312 toggles to couple the first terminal of the switch 312 to the third terminal of the switch 312.

In the example of FIG. 3, responsive to the first terminal of the switch 312 being coupled to the third terminal of the switch 312, the amplifier 302 compares the monitored temperature provided by the temperature sensor 224 to the upper threshold provided by the upper threshold terminal 316. In the example of FIG. 3, responsive to the monitored temperature provided by the temperature sensor 224 being less than the upper threshold provided by the upper threshold terminal 316, the amplifier 302 provides a logic low value. As such, after the switch 312 is initially toggled to couple the first terminal of the switch 312 to the third terminal of the switch 312, the driver 210 continues to disable the transistor 212 and the transistor 216, allowing the transistor 212 and the transistor 216 to return to a breakdown mode of operation if a voltage across the switch circuit 116_{A} is at a breakdown level.

In the example of FIG. 3, responsive to the monitored temperature provided by the temperature sensor 224 being greater than or equal to the upper threshold provided by the upper threshold terminal 316, the amplifier 302 generates a logic high value. Responsive to a logic high value at the output of the amplifier 302, the driver 210 enables the transistor 212 and the transistor 216, allowing the transistor 212 and the transistor 216 to cool. Also, responsive to a logic high value at the output of the amplifier 302, the switch 312 toggles to couple the second terminal of the switch 312 to the third terminal of the switch 312.

As described above, responsive to the fault state being set, the amplifier 318 compares the cleared fault threshold provided by the cleared fault threshold terminal 320 to the monitored temperature provided by the temperature sensor 224. In the example of FIG. 3, responsive to the cleared fault threshold provided by the cleared fault threshold terminal 320 being greater than or equal to the monitored temperature provided by the temperature sensor 224, the amplifier 318 generates a logic high value. Responsive to the logic high value at the output of the amplifier 318, the OR gate 322 provides a logic high value to the clear terminal of the flip-flop 308. For example, responsive to the logic high value at the output of the OR gate 322, the flip-flop 308 generates a logic low value. Responsive to the logic low value at the output of the flip-flop 308, the switch 306 toggles to couple the first terminal of the switch 306 to the third terminal of the switch 306. Also, responsive to the logic low value at the output of the flip-flop 308, the amplifier 318 is disabled.

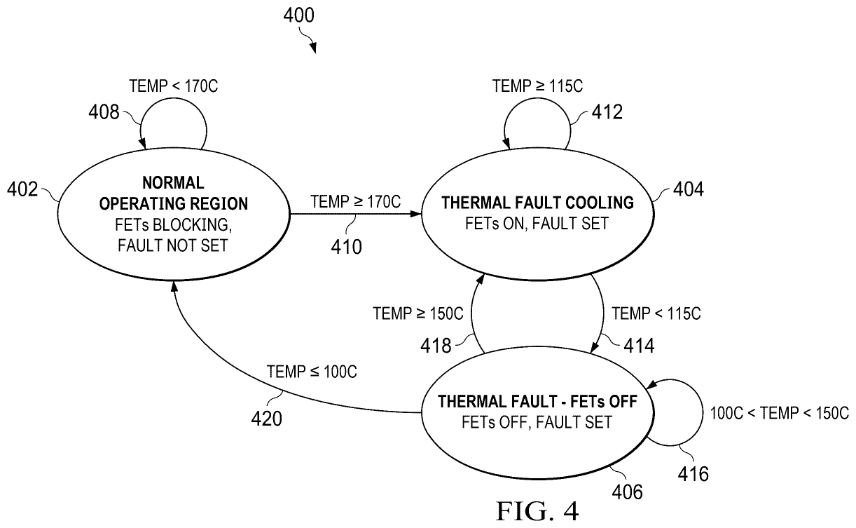

FIG. 4 is an example state diagram 400 representative of example operations of the switch circuit 116_{A} of FIGS. 1 and 2. In the example of FIG. 4, the state diagram 400 includes a first example state 402 representative of normal operating conditions of the switch circuit 116_{A}, a second example state 404 representative of a thermal fault and during which the transistor 212 and the transistor 216 are cooled, and a third example state 406 representative of the thermal fault and during which at least one of the transistor 212 or the transistor 216 is permitted to conduct avalanche current. In the example of FIG. 4, the temperature-based control circuit 220 regulates the temperature of at least one of the transistor 212 or the transistor 216 responsive to a sensed temperature monitored by the temperature sensor 224.

In the example of FIG. 4, in the state 402, the transistor 212 and the transistor 216 are disabled and blocking the voltage across the switch circuit 116_{A}. Also, in the state 402, the fault state maintained by the temperature-based control circuit 220 is not set. In the example of FIG. 4, in the state 402, the temperature-based control circuit 220 monitors the temperature sensor 224 and determines whether the monitored temperature is greater than or equal to the fault threshold of 170° C. Responsive to the temperature-based control circuit 220 determining that the monitored temperature is less than the fault threshold, the switch circuit 116_{A} returns to the state 402 at a first example transition 408. Responsive to the temperature-based control circuit 220 determining that the monitored temperature is greater than or equal to the fault threshold, the switch circuit 116_{A} changes to the state 404 at a second example transition 410.

In the example of FIG. 4, in the state 404, the transistor 212 and the transistor 216 are enabled and the fault state maintained by the temperature-based control circuit 220 is set. In the example of FIG. 4, in the state 404, the temperature-based control circuit 220 monitors the temperature sensor 224 and determines whether the monitored temperature is greater than or equal to the lower threshold of 115° C. Responsive to the temperature-based control circuit 220 determining that the monitored temperature is greater than or equal to the lower threshold, the switch circuit 116_{A} returns to the state 404 at a third example transition 412. Responsive to the temperature-based control circuit 220 determining that the monitored temperature is less than the lower threshold, the switch circuit 116_{A} changes to the state 406 at a fourth example transition 414.

In the example of FIG. 4, in the state 406, the transistor 212 and the transistor 216 are disabled and the fault state maintained by the temperature-based control circuit 220 is set. In the example of FIG. 4, in the state 406, the temperature-based control circuit 220 monitors the temperature sensor 224 and determines whether the monitored temperature is greater than or equal to the upper threshold of 150° C. Also, in the state 406, the temperature-based control circuit 220 determines whether the cleared fault threshold of 100° C. is greater than or equal to the monitored temperature provided by the temperature sensor 224. In this manner, the temperature-based control circuit 220 determines whether the monitored temperature provided by the temperature sensor 224 is between the upper threshold or 150° C. and the cleared fault threshold of 100° C.

In the example of FIG. 4, responsive to the temperature-based control circuit 220 determining that the monitored temperature is less than the upper threshold and greater than the cleared fault threshold, the switch circuit 116_{A} returns to the state 406 at a fifth example transition 416. Responsive to the temperature-based control circuit 220 determining that the monitored temperature is greater than or equal to the upper threshold, the switch circuit 116_{A} returns to the state 404 at a sixth example transition 418. Responsive to the temperature-based control circuit 220 determining that the monitored temperature is less than or equal to the cleared fault threshold, the switch circuit 116_{A} returns to the state 402 at a seventh example transition 420.

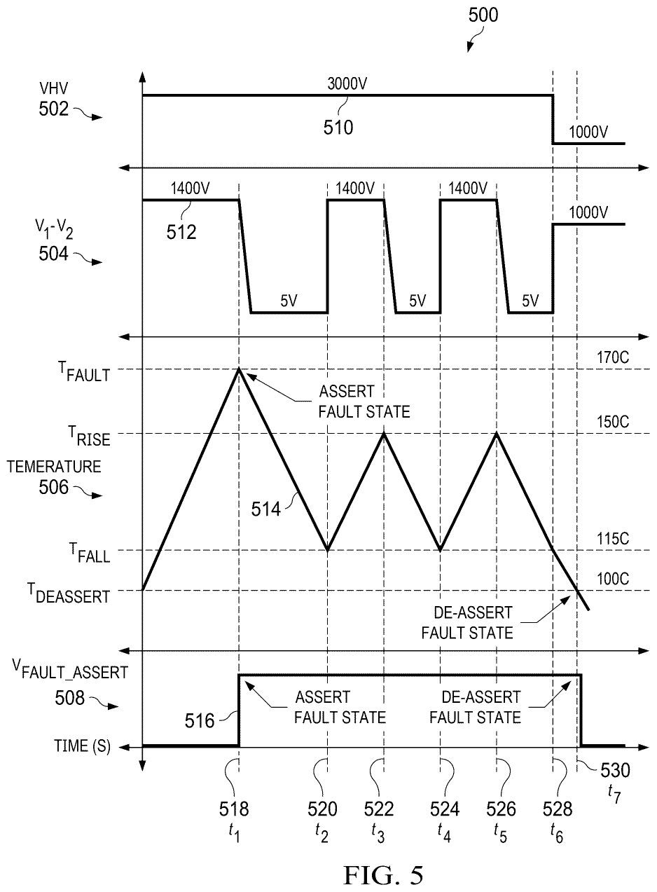

FIG. 5 is a graphical illustration of an example timing diagram 500 representative of the operation of the switch circuit 116_{A} of FIGS. 1 and 2. In the example of FIG. 5, the timing diagram 500 includes a first example graph 502, a second example graph 504, a third example graph 506, and a fourth example graph 508. In the example of FIG. 5, the graph 502 and the graph 504 depict voltage in volts versus time in seconds(s). Also, the graph 506 depicts temperature in degrees Celsius versus time in seconds and the graph 508 depicts a binary signal versus time in seconds.

In the example of FIG. 5, the graph 502 includes a first example plot 510 depicting the voltage (V_{HV}) provided by the voltage source 104. In the example of FIG. 5, the graph 504 includes a second example plot 512 depicting the voltage (V₁-V₂) across the first terminal of the switch circuit 116_{A} and the second terminal of the switch circuit 116_{A}. Also, in the example of FIG. 5, the graph 506 includes a third example plot 514 depicting the monitored temperature provided by the temperature sensor 224. In the example of FIG. 5, the graph 508 includes a fourth example plot 516 depicting the binary signal V_{FAULT_ASSERT} provided by the flip-flop 308.

In the example of FIG. 5, before a first example time 518 (t₁), the voltage source 104 provides a voltage of 3,000 V, for example, during a Hi-Pot test of the system 100. Before the time 518 (t₁), the transistor 212 and the transistor 216 are disabled. As such, the voltage across the switch circuit 116_{A} is at a breakdown level of 1,400 V responsive to the 3,000 V provided by the voltage source 104. Because the voltage across the switch circuit 116_{A} is at a breakdown level, at least one of the transistor 212 or the transistor 216 enters a breakdown mode of operation in which the at least one of the transistor 212 or the transistor 216 to conduct avalanche current and heat. Thus, the temperature of at least one of the transistor 212 or the transistor 216 increases and the monitored temperature provided by the temperature sensor 224 increases.

In the example of FIG. 5, at the time 518 (t₁), the monitored temperature provided by the temperature sensor 224 reaches the fault threshold (T_{FAULT}) of 170° C. Responsive to the monitored temperature provided by the temperature sensor 224 satisfying (for example, being greater than or equal to) the fault threshold (T_{FAULT}) of 170° C., the amplifier 302 provides a signal to the driver 210. Responsive to the signal at the output of the amplifier 302, the driver 210 enables the transistor 212 and the transistor 216 to regulate the voltage across the switch circuit 116_{A} from a breakdown level of 1,400 V to a supply level of 5 V for the driver 210 and the temperature-based control circuit 220. Also, responsive to the signal at the output of the amplifier 302, the flip-flop 308 asserts the fault state.

In the example of FIG. 5, between the time 518 (t₁) and a second example time 520 (t₂), the voltage source 104 continues to provide a voltage of 3,000 V. Because the transistor 212 and the transistor 216 are enabled, the voltage across the switch circuit 116_{A} is regulated to 5 V between the time 518 (t₁) and the time 520 (t₂). Thus, the temperature of at least one of the transistor 212 or the transistor 216 decreases and the monitored temperature provided by the temperature sensor 224 decreases.

In the example of FIG. 5, at the time 520 (t₂), the monitored temperature provided by the temperature sensor 224 reaches the lower threshold (T_{FALL}) of 115° C. Responsive to the monitored temperature provided by the temperature sensor 224 not satisfying (for example, being less than) the lower threshold (T_{FALL}) of 115° C., the amplifier 302 provides a signal to the driver 210. Responsive to the signal at the output of the amplifier 302, the driver 210 disables the transistor 212 and the transistor 216. As such, the voltage across the switch circuit 116_{A} returns to a breakdown level of 1,400 V. Thus, the temperature of at least one of the transistor 212 or the transistor 216 increases and the monitored temperature provided by the temperature sensor 224 increases.

In the example of FIG. 5, between the time 520 (t₂) and a third example time 522 (t₃), the voltage source 104 continues to provide a voltage of 3,000 V. Between the time 520 (t₂) and the time 522 (t₃), the transistor 212 and the transistor 216 are disabled. As such, the voltage across the switch circuit 116_{A} is 1,400 V responsive to the 3,000 V provided by the voltage source 104. Thus, the temperature of at least one of the transistor 212 or the transistor 216 increases and the monitored temperature provided by the temperature sensor 224 increases.

In the example of FIG. 5, at the time 522 (t₃), the monitored temperature provided by the temperature sensor 224 reaches the upper threshold (T_{RISE}) of 150° C. Responsive to the monitored temperature provided by the temperature sensor 224 satisfying (for example, being greater than or equal to) the upper threshold (T_{RISE}) of 150° C., the amplifier 302 provides a signal to the driver 210. Responsive to the signal at the output of the amplifier 302, the driver 210 enables the transistor 212 and the transistor 216. As described above, the driver 210 enables the transistor 212 and the transistor 216 to regulate the voltage across the switch circuit 116_{A} from a breakdown level of 1,400 V to a supply level of 5 V for the driver 210 and the temperature-based control circuit 220.

In the example of FIG. 5, between the time 522 (t₃) and a fourth example time 524 (t₄), the voltage source 104 continues to provide a voltage of 3,000 V. Because the transistor 212 and the transistor 216 are enabled, the voltage across the switch circuit 116_{A} is regulated to 5 V between the time 522 (t₃) and the time 524 (t₄). Thus, the temperature of at least one of the transistor 212 or the transistor 216 decreases and the monitored temperature provided by the temperature sensor 224 decreases.

In the example of FIG. 5, at the time 524 (t₄), the monitored temperature provided by the temperature sensor 224 reaches the lower threshold (T_{FALL}) of 115° C. Responsive to the monitored temperature provided by the temperature sensor 224 not satisfying (for example, being less than) the lower threshold (T_{FALL}) of 115° C., the amplifier 302 provides a signal to the driver 210. Responsive to the signal at the output of the amplifier 302, the driver 210 disables the transistor 212 and the transistor 216. As such, the voltage across the switch circuit 116_{A} returns to a breakdown level of 1,400 V. Thus, the temperature of at least one of the transistor 212 or the transistor 216 increases and the monitored temperature provided by the temperature sensor 224 increases.

In the example of FIG. 5, between the time 524 (t₄) and a fifth example time 526 (t₅), the voltage source 104 continues to provide a voltage of 3,000 V. Between the time 524 (t₄) and the time 526 (t₅), the transistor 212 and the transistor 216 are disabled. As such, the voltage across the switch circuit 116_{A} is 1,400 V responsive to the 3,000 V provided by the voltage source 104. Thus, the temperature of at least one of the transistor 212 or the transistor 216 increases and the monitored temperature provided by the temperature sensor 224 increases.

In the example of FIG. 5, at the time 526 (t₅), the monitored temperature provided by the temperature sensor 224 reaches the upper threshold (T_{RISE}) of 150° C. Responsive to the monitored temperature provided by the temperature sensor 224 satisfying (for example, being greater than or equal to) the upper threshold (T_{RISE}) of 150° C., the amplifier 302 provides a signal to the driver 210. Responsive to the signal at the output of the amplifier 302, the driver 210 enables the transistor 212 and the transistor 216. As described above, the driver 210 enables the transistor 212 and the transistor 216 to regulate the voltage across the switch circuit 116_{A} from a breakdown level of 1,400 V to a supply level of 5 V for the driver 210 and the temperature-based control circuit 220.

In the example of FIG. 5, between the time 526 (t₅) and a sixth example time 528 (t₆), the voltage source 104 continues to provide a voltage of 3,000 V. Because the transistor 212 and the transistor 216 are enabled, the voltage across the switch circuit 116_{A} is regulated to 5 V between the time 526 (t₅) and the time 528 (t₆). Thus, the temperature of at least one of the transistor 212 or the transistor 216 decreases and the monitored temperature provided by the temperature sensor 224 decreases. In the example of FIG. 5, at the time 528 (16), the monitored temperature provided by the temperature sensor 224 reaches the lower threshold (T_{FALL}) of 115° C. Responsive to the monitored temperature provided by the temperature sensor 224 not satisfying (for example, being less than) the lower threshold (T_{FALL}) of 115° C., the amplifier 302 provides a signal to the driver 210. Responsive to the signal at the output of the amplifier 302, the driver 210 disables the transistor 212 and the transistor 216.

In the example of FIG. 5, at the time 528 (t₆), the voltage provided by the voltage source 104 transitions from 3,000 V to 1,000 V. For example, the Hi-Pot test of the system 100 ends at the time 528 (t₆). In the example of FIG. 5, the voltage across the switch circuit 116_{A} transitions from 5 V to 1,000 V responsive to the 3,000 V provided by the voltage source 104. As such, the transistor 212 and the transistor 216 are not in a breakdown mode of operation and do not conduct avalanche current.

Thus, the temperature of at least one of the transistor 212 or the transistor 216 continues to decrease and the monitored temperature provided by the temperature sensor 224 continues to decrease. In the example of FIG. 5, at a seventh example time 530 (t₇), the monitored temperature provided by the temperature sensor 224 reaches the cleared fault threshold (T_{DEASSERT}) of 100° C. Responsive to the monitored temperature provided by the temperature sensor 224 not satisfying (for example, being less than) the cleared fault threshold (T_{DEASSERT}) of 100° C., the amplifier 318 provides a signal to the flip-flop 308. Responsive to the signal at the output of the amplifier 318, the flip-flop 308 de-asserts the fault state.

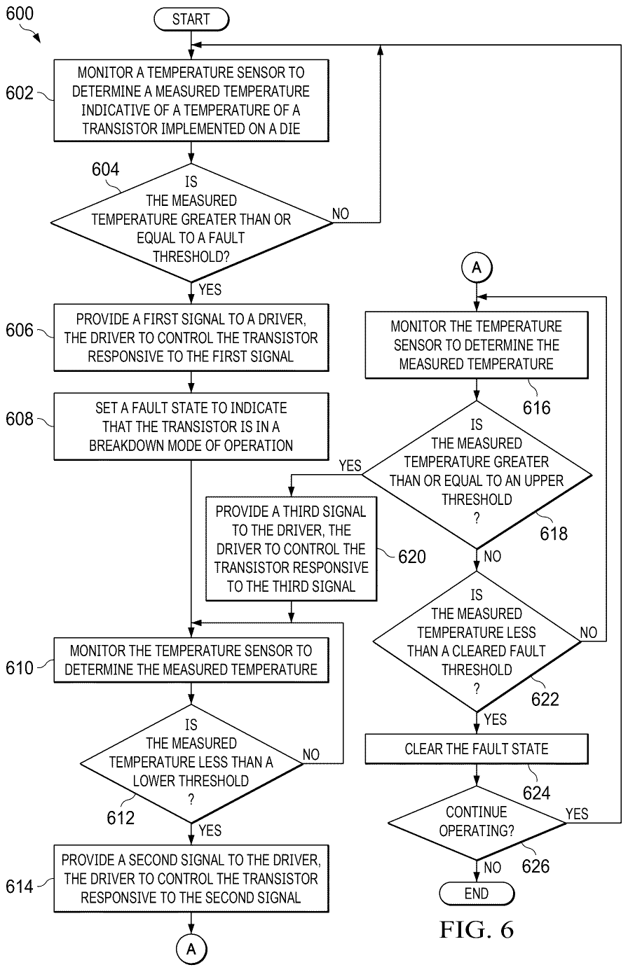

FIG. 6 is a flowchart representative of at least one of example machine-readable instructions or example operations 600 that may be at least one of executed, instantiated, or performed by programmable circuitry to implement the temperature-based control circuit 220 of FIGS. 2 and 3. The at least one of the example machine-readable instructions or the example operations 600 of FIG. 6 begin at block 602, at which the temperature-based control circuit 220 monitors a temperature sensor to determine a measured temperature indicative of a temperature of a transistor implemented on a die. For example, the amplifier 302 monitors the temperature sensor 224 to determine a measured temperature indicative of a temperature of at least one of the transistor 212 or the transistor 216. In the example of FIG. 6, the transistor is disabled.

In the example of FIG. 6, at block 604, the temperature-based control circuit 220 determines whether the measured temperature is greater than or equal to a fault threshold. For example, the amplifier 302 determines whether the measured temperature is greater than or equal to a fault threshold of 170° C. Responsive to the temperature-based control circuit 220 determining that the measured temperature is not greater than or equal to the fault threshold (block 604: NO), the at least one of the machine-readable instructions or the operations 600 return to block 602. Responsive to the temperature-based control circuit 220 determining that the measured temperature is greater than or equal to the fault threshold (block 604: YES), the at least one of the machine-readable instructions or the operations 600 proceed to block 606.

In the example of FIG. 6, at block 606, the temperature-based control circuit 220 provides a first signal to a driver where the driver is to control the transistor responsive to the first signal to dissipate heat. For example, the amplifier 302 provides the first signal to the driver 210 and the driver 210 is to enable the transistor 212 and the transistor 216 responsive to the first signal. In the example of FIG. 6, at block 608, the temperature-based control circuit 220 sets a fault state to indicate that the transistor is in a breakdown mode of operation. For example, the flip-flop 308 sets a fault state to indicate that at least one of the transistor 212 or the transistor 216 is in a breakdown mode of operation.

In the example of FIG. 6, at block 610, the temperature-based control circuit 220 monitors the temperature sensor to determine the measured temperature. For example, the amplifier 302 monitors the temperature sensor 224 to determine the measured temperature indicative of the temperature of at least one of the transistor 212 or the transistor 216. In the example of FIG. 6, at block 612, the temperature-based control circuit 220 determines whether the measured temperature is less than a lower threshold. For example, the amplifier 302 determines whether the measured temperature is less than a lower threshold of 115° C. Responsive to the temperature-based control circuit 220 determining that the measured temperature is not less than the lower threshold (block 612: NO), the at least one of the machine-readable instructions or the operations 600 return to block 610.

Responsive to the temperature-based control circuit 220 determining that the measured temperature is less than the lower threshold (block 612: YES), the at least one of the machine-readable instructions or the operations 600 proceed to block 614. At block 614, the temperature-based control circuit 220 provides a second signal to the driver where the driver is to control the transistor responsive to the second signal. For example, the amplifier 302 provides the second signal to the driver 210 and the driver 210 is to disable the transistor 212 and the transistor 216 responsive to the second signal. In the example of FIG. 6, at block 616, the temperature-based control circuit 220 monitors the temperature sensor to determine the measured temperature. For example, the amplifier 302 and the amplifier 318 monitor the temperature sensor 224 to determine the measured temperature indicative of the temperature of at least one of the transistor 212 or the transistor 216.

In the example of FIG. 6, at block 618, the temperature-based control circuit 220 determines whether the measured temperature is greater than or equal to the upper threshold. For example, the amplifier 302 determines whether the measured temperature is greater than or equal to an upper threshold of 150° C. Responsive to the temperature-based control circuit 220 determining that the measured temperature is greater than or equal to the upper threshold (block 618: YES), the at least one of the machine-readable instructions or the operations 600 proceed to block 620. In the example of FIG. 6, at block 620, the temperature-based control circuit 220 provides a third signal to the driver where the driver is to control the transistor responsive to the third signal to dissipate heat. For example, the amplifier 302 provides the third signal to the driver 210 and the driver 210 is to enable the transistor 212 and the transistor 216 responsive to the third signal.

In the example of FIG. 6, responsive to the temperature-based control circuit 220 determining that the measured temperature is not greater than or equal to the upper threshold (block 618: NO), the at least one of the machine-readable instructions or the operations 600 proceed to block 622. In the example of FIG. 6, at block 622, the temperature-based control circuit 220 determines whether the measured temperature is less than a cleared fault threshold. For example, the amplifier 318 determines whether the measured temperature is less than a cleared fault threshold of 100° C. Responsive to the temperature-based control circuit 220 determining that the measured temperature is not less than the cleared fault threshold (block 622: NO), the at least one of the machine-readable instructions or the operations 600 return to block 616.

Responsive to the temperature-based control circuit 220 determining that the measured temperature is less than the cleared fault threshold (block 622: YES), the at least one of the machine-readable instructions or the operations 600 proceed to block 624. At block 624, the temperature-based control circuit 220 clears the fault state. For example, the flip-flop 308 clears the fault state. In the example of FIG. 6, at block 626, the temperature-based control circuit 220 determines whether to continue operating. For example, the temperature-based control circuit 220 determines to continue operating if the temperature-based control circuit 220 is powered. Responsive to the temperature-based control circuit 220 determining to continue operating (block 626: YES), the at least one of the machine-readable instructions or the operations 600 return to block 602. Responsive to the temperature-based control circuit 220 determining not to continue operating (block 626: NO), the at least one of the machine-readable instructions or the operations 600 terminate.

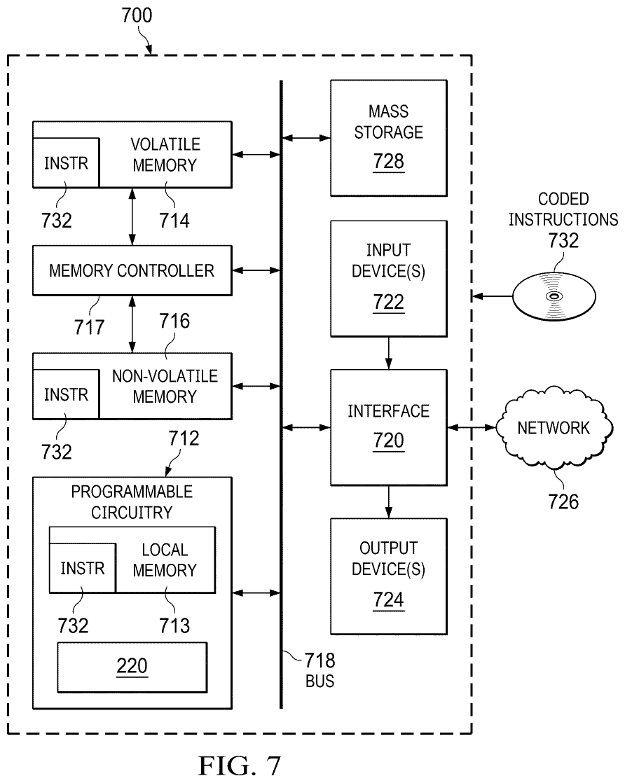

FIG. 7 is a block diagram of an example programmable circuitry platform 700 structured to one or a combination of execute or instantiate the at least one of the machine-readable instructions or the operations 600 of FIG. 6 to implement the temperature-based control circuit 220 of FIGS. 2 and 3. The programmable circuitry platform 700 can be, for example, an electrical system in a vehicle such as an EV or HEV. The programmable circuitry platform 700 of the example includes programmable circuitry 712. The programmable circuitry 712 of the example is hardware. For example, the programmable circuitry 712 can be implemented by one or more integrated circuits, logic circuits, FPGAs, microprocessors, CPUs, GPUs, DSPs, or microcontrollers from any desired family or manufacturer. The programmable circuitry 712 may be implemented by at least one programmable circuit such as one or more semiconductor based (for example, silicon based) devices. In this example, the programmable circuitry 712 implements the example temperature-based control circuit 220.

The programmable circuitry 712 of the example includes a local memory 713 (for example, a cache, registers, etc.). The programmable circuitry 712 of the example is in communication with main memory 714, 716, which includes a volatile memory 714 and a non-volatile memory 716, by a bus 718. The volatile memory 714 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 716 may be implemented by one or a combination of flash memory or any other desired type of memory device. Access to the main memory 714, 716 of the example is controlled by a memory controller 717. In some examples, the memory controller 717 may be implemented by one or more integrated circuits, logic circuits, microcontrollers from any desired family or manufacturer, or any other type of circuitry to manage the flow of data going to and from the main memory 714, 716.

The programmable circuitry platform 700 of the example also includes interface circuitry 720. The interface circuitry 720 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the example, one or more input devices 722 are connected to the interface circuitry 720. The input device(s) 722 permit(s) a user (such as a human user, a machine user, etc.) to enter one of or a combination of data or commands into the programmable circuitry 712. The input device(s) 722 can be implemented by, for example, one of or a combination of an audio sensor, a microphone, a camera (still or video), a keyboard, a button, a mouse, a touchscreen, a trackpad, a trackball, an isopoint device, or a voice recognition system.

One or more output devices 724 are also connected to the interface circuitry 720 of the example. The output device(s) 724 can be implemented, for example, by one of or a combination of display devices (for example, a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 720 of the example, thus, includes one of or a combination of a graphics driver card, a graphics driver chip, or graphics processor circuitry such as a GPU.

The interface circuitry 720 of the example also includes a communication device such as one of or a combination of a transmitter, a receiver, a transceiver, a modem, a residential gateway, a wireless access point, or a network interface to facilitate exchange of data with external machines (for example, computing devices of any kind) by a network 726. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 700 of the example also includes one or more mass storage discs or devices 728 to store one or more of firmware, software, or data. Examples of such mass storage discs or devices 728 include one or more magnetic storage devices (such as floppy disk, drives, HDDs, etc.), optical storage devices, RAID systems, or solid-state storage discs or devices such as flash memory devices and SSDs.

The machine-readable instructions 732, which may be implemented by the at least one of the machine-readable instructions or the operations 600 of FIG. 6, may be stored in one of or a combination of the mass storage device 728, in the volatile memory 714, in the non-volatile memory 716, or on at least one non-transitory computer-readable storage medium which may be removable.

While an example manner of implementing the temperature-based control circuit 220 of FIG. 2 is illustrated in FIG. 3, one or more of the elements, processes, or devices illustrated in FIG. 3 may be combined, divided, re-arranged, omitted, eliminated, or implemented in any other way. Further, the example amplifier 302, the example fault threshold terminal 304, the example switch 306, the example flip-flop 308, the example logic high terminal 310, the example switch 312, the example lower threshold terminal 314, the example upper threshold terminal 316, the example amplifier 318, the example cleared fault threshold terminal 320, the example OR gate 322, the example power on reset circuitry 324, or, more generally, the example temperature-based control circuit 220 of FIGS. 2 and 3, may be implemented by hardware alone or by hardware in combination with software and firmware. Thus, for example, any of the example amplifier 302, the example fault threshold terminal 304, the example switch 306, the example flip-flop 308, the example logic high terminal 310, the example switch 312, the example lower threshold terminal 314, the example upper threshold terminal 316, the example amplifier 318, the example cleared fault threshold terminal 320, the example OR gate 322, the example power on reset circuitry 324, or, more generally, the example temperature-based control circuit 220, could be implemented by programmable circuitry in combination with one or more machine-readable instructions (for example, firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example temperature-based control circuit 220 of FIG. 3 may include one or more elements, processes, or devices in addition to, or instead of, those illustrated in FIG. 3, or may include more than one of any or all of the illustrated elements, processes and devices.

Flowchart(s) representative of example machine-readable instructions, which may be executed by programmable circuitry to at least one of implement or instantiate the temperature-based control circuit 220 of FIGS. 2 and 3 or representative of example operations which may be performed by programmable circuitry to at least one of implement or instantiate the temperature-based control circuit 220 of FIGS. 2 and 3, are shown in FIG. 6. The machine-readable instructions may be one or more executable programs or portion(s) of one or more executable programs for execution by programmable circuitry such as the programmable circuitry 712 shown in the example programmable circuitry platform 700 described below in connection with FIG. 7 and may be one or more function(s) or portion(s) of functions to be performed by the example programmable circuitry (such as an FPGA). In some examples, an operation, a task, etc., is carried out or performed in an automated manner in the real-world responsive to the machine-readable instructions. As used herein, “automated” means without human involvement.

The program may be embodied in instructions (for example, at least one of software or firmware) stored on one or more non-transitory computer-readable or machine-readable storage medium such as one of or a combination of cache memory, a magnetic-storage device or disk, an optical-storage device or disk, etc.), a Redundant Array of Independent Disks (RAID), a register, ROM, a solid-state drive (SSD), SSD memory, non-volatile memory (such as electrically erasable programmable read-only memory (EEPROM), flash memory, etc.), volatile memory (such as Random Access Memory (RAM) of any type, etc.), or any other storage device or storage disk. The instructions of the non-transitory computer-readable or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (for example, a server and a client hardware device). For example, the client hardware device may be implemented by an endpoint client hardware device (for example, a hardware device associated with at least one of a human user or a machine user) or an intermediate client hardware device gateway (such as a radio access network (RAN)) that may facilitate communication between a server and an endpoint client hardware device. Similarly, the non-transitory computer-readable storage medium may include one or more mediums. Further, although the example program is described with reference to the flowchart(s) illustrated in FIG. 6, many other methods of implementing the example temperature-based control circuit 220 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (such as processor circuitry, discrete analog circuitry, discrete digital circuitry, integrated analog circuitry, integrated digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (such as a single-core processor (for example, a single core CPU), a multi-core processor (such as a multi-core CPU, an XPU, etc.)). As used herein, programmable circuitry includes any type(s) of circuitry that may be programmed to perform a desired function such as, for example, one of or a combination of a CPU or an FPGA. The programmable circuitry may include one or more CPUs or one or more FPGAs located in the same package (for example, the same integrated circuit (IC) package or in two or more separate housings), one or more CPUs or FPGAs in a single machine, one or multiple CPUs or FPGAs distributed across multiple servers of a server rack, multiple processors distributed across one or more server racks. Also or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller unit (MCU), a programmable system on chip (PSoC), etc., or any combination(s) thereof in any of the contexts described above.

The machine-readable instructions described herein may be stored in one or more of a compressed format, an encrypted format, a fragmented format, a compiled format, an executable format, a packaged format, etc. Machine-readable instructions as described herein may be stored as data (for example, computer-readable data, machine-readable data, one or more bits (for example, one or more computer-readable bits, one or more machine-readable bits, etc.), a bitstream (for example, a computer-readable bitstream, a machine-readable bitstream, etc.), etc.) or a data structure (for example, as portion(s) of instructions, code, representations of code, etc.) that may be utilized to create, manufacture, or produce machine-executable instructions. For example, the machine-readable instructions may be fragmented and stored on one or more storage devices, disks or computing devices (such as servers) located at the same or different locations of a network or collection of networks. The machine-readable instructions may require one or more of installation, modification, adaptation, updating, combining, supplementing, configuring, decryption, decompression, unpacking, distribution, reassignment, compilation, etc., in order to render them directly readable, interpretable, or executable by a computing device or other machine. For example, the machine-readable instructions may be stored in multiple parts, which are individually compressed, encrypted, or stored on separate computing devices, where the parts when decrypted, decompressed, or combined form a set of one or more computer-executable or machine-executable instructions that implement one or more functions or operations that may together form a program such as that described herein.

In another example, the machine-readable instructions may need to be adjusted (for example, settings stored, data input, network addresses recorded, etc.) before the machine-readable instructions or the corresponding program(s) can be executed in whole or in part. Thus, machine-readable, computer-readable or machine-readable media, as used herein, may include one or a combination of instructions and program(s) regardless of the particular format or state of the machine-readable instructions or program(s). The machine-readable instructions described herein can be represented by any past, present, or future instruction language, scripting language, programming language, etc. For example, the machine-readable instructions may be represented using any of the following languages: C, C++, C-Sharp, etc.

As mentioned above, the example operations of FIG. 6 may be implemented using executable instructions (for example, at least one of computer-readable instructions or machine-readable instructions) stored on one or more non-transitory computer-readable or machine-readable media. As used herein, the terms non-transitory computer-readable medium, non-transitory computer-readable storage medium, non-transitory machine-readable medium, and non-transitory machine-readable storage medium are expressly defined to include any type of computer-readable storage device or storage disk and to exclude propagating signals and to exclude transmission media. Examples of such non-transitory computer-readable medium, non-transitory computer-readable storage medium, non-transitory machine-readable medium, or non-transitory machine-readable storage medium include one or more optical storage devices, magnetic storage devices, a flash memory, a read-only memory (ROM), a cache, a RAM of any type, a register, or any other storage device or storage disk in which information is stored for any duration (for example, for extended time periods, permanently, for brief instances, for temporarily buffering, for caching of the information). As used herein, the terms “non-transitory computer-readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer-readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be adjusted by computer-readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (for example, comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (such as “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, for example, the same entity or object. Also, although individual features may be included in different examples or claims, these may possibly be combined, and the inclusion in different examples or claims does not imply that a combination of features is at least one of not feasible or advantageous.

As used herein, connection references (for example, attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples.

In some examples, the descriptor “first” may be used to refer to an element in the detailed description, while the same element may be referred to in a claim with a different descriptor such as “second” or “third.” In such instances, such descriptors are used merely for identifying those elements distinctly within the context of the description (for example, within a claim) in which the elements might, for example, otherwise share a same name.

As used herein, the phrase “in communication,” including variations thereof, encompasses one of or a combination of direct communication or indirect communication through one or more intermediary components, and does not require direct physical (for example, wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (such as an application specific circuit (ASIC)) structured to perform specific operation(s) and including one or more semiconductor-based logic devices (such as electrical hardware implemented by one or more transistors), or (ii) one or more general purpose semiconductor-based electrical circuits programmable with instructions to perform one or more specific functions(s) or operation(s) and including one or more semiconductor-based logic devices (such as electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (such as one or more FPGAs, one or more CPUs, one or more GPUs, one or more NPUs, one or more DSPs, etc., and any combination(s) thereof), and orchestration technology (for example, application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (for example, at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as at least one of voltage sources or current sources) may instead include only the semiconductor elements within a single physical device (for example, at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. Unless otherwise stated, “about” or “approximately” preceding a value means+/−10 percent of the stated value, or, if the value is zero, a reasonable range of values around zero.

Modifications are possible in the described examples, and other examples are possible, within the scope of the claims.

From the foregoing, it will be appreciated that example systems, apparatus, articles of manufacture, and methods have been described that provide thermal avalanche protection with lower temperature stress and without sacrificing normal operating temperature range. Described systems, apparatus, articles of manufacture, and methods set a thermal fault condition and regulate the temperature of a die to a lower average temperature. For example, described examples initially engage thermal regulation when the die junction temperature is within the physical limits (for example, 170° C.) but above the normal operating region (for example, −40° C. to 150° C.). Once the fault is detected and remains, examples described herein reduce sensing thresholds to permit a controlled switch to sustain high fault stress for an extended time. As such, examples described herein allow devices to achieve higher avalanche current capability.

Described systems, apparatus, articles of manufacture, and methods improve the efficiency of using a computing device by increasing the amount of avalanche current the computing device can withstand and decreasing the area consumed on a chip as compared to other approaches. For example, by regulating device temperature as described herein, devices can conduct up to 3 mA of avalanche current for up to 60 seconds whereas other approaches support less than 1 mA of avalanche current. Also, other approaches require a series relay or a current limiting resistor that is three to four times physically larger than in described examples to withstand Hi-Pot test conditions. Described systems, apparatus, articles of manufacture, and methods are also directed to one or more improvement(s) in the operation of a machine such as a computer or other electronic, electromechanical, or mechanical device.

What is claimed is:

1. An apparatus comprising:
a first transistor having a control terminal, a first terminal adapted to be coupled to a first resistor, and a second terminal adapted to be coupled to a second resistor;
a second transistor having a control terminal, a first terminal, and a second terminal, the control terminal adapted to be coupled to a ground terminal, the first terminal coupled to the first terminal of the first transistor;
a driver having a supply terminal, an input, and an output, the supply terminal coupled to the second terminal of the second transistor, the output coupled to the control terminal of the first transistor; and
a temperature-based control circuit having a supply terminal coupled to the second terminal of the second transistor and an output coupled to the input of the driver, the temperature-based control circuit capable of:
monitoring a temperature sensor to determine a measured temperature indicative of a temperature of the first transistor;
responsive to the measured temperature being greater than or equal to a fault threshold, providing a first signal to the driver, the driver to control the first transistor responsive to the first signal;
responsive to the measured temperature being less than a lower threshold, providing a second signal to the driver, the driver to control the first transistor responsive to the second signal; and
responsive to the measured temperature being greater than or equal to an upper threshold, providing a third signal to the driver, the driver to control the first transistor responsive to the third signal, the upper threshold being less than the fault threshold.

2. The apparatus of claim 1, wherein the temperature-based control circuit is capable of:
responsive to the measured temperature being greater than or equal to the fault threshold, setting a fault state; and
responsive to the measured temperature being less than a cleared fault threshold, clearing the fault state, the cleared fault threshold less than the lower threshold.

3. The apparatus of claim 2, wherein the temperature-based control circuit is capable of, responsive to the measured temperature not being greater than or equal to the upper threshold, determining whether the measured temperature is less than the cleared fault threshold.

4. The apparatus of claim 2, wherein the fault state is to:
indicate that the first transistor is in a breakdown mode of operation; and
prevent the temperature-based control circuit from providing a fourth signal to the driver unless the measured temperature is greater than or equal to the fault threshold, the driver to control the first transistor responsive to the fourth signal.

5. The apparatus of claim 1, wherein the measured temperature being greater than or equal to the fault threshold indicates that the first transistor is in a breakdown mode of operation, and the temperature-based control circuit is capable of:
providing the first signal to the driver, the driver to control the first transistor responsive to the first signal to dissipate heat; and
responsive to the measured temperature being less than the lower threshold, providing a fourth signal to the driver, the driver to control the first transistor responsive to the fourth signal to allow for the first transistor to return to the breakdown mode of operation if a voltage across an integrated circuit is at a breakdown level, the first transistor packaged in the integrated circuit.

6. The apparatus of claim 1, wherein the temperature-based control circuit is capable of providing the first signal to the driver, the driver to control the first transistor responsive to the first signal to regulate a voltage across an integrated circuit from a breakdown level to a supply level for the temperature-based control circuit and the driver, the first transistor packaged in the integrated circuit.

7. The apparatus of claim 1, wherein the temperature corresponds to a junction temperature of the first transistor.

8. A method comprising:
determining, with a temperature-based control circuit, a measured temperature indicative of a temperature of a transistor;
responsive to the measured temperature being greater than or equal to a fault threshold, providing, with the temperature-based control circuit, a first signal to a driver, the driver to control the transistor responsive to the first signal;
responsive to the measured temperature being less than a lower threshold, providing, with the temperature-based control circuit, a second signal to the driver, the driver to control the transistor responsive to the second signal; and
responsive to the measured temperature being greater than or equal to an upper threshold, providing, with the temperature-based control circuit, a third signal to the driver, the driver to control the transistor responsive to the third signal, the upper threshold being less than the fault threshold.

9. The method of claim 8, including:
responsive to the measured temperature being greater than or equal to the fault threshold, setting a fault state; and
responsive to the measured temperature being less than a cleared fault threshold, clearing the fault state, the cleared fault threshold less than the lower threshold.

10. The method of claim 9, including, responsive to the measured temperature not being greater than or equal to the upper threshold, determining whether the measured temperature is less than the cleared fault threshold.

11. The method of claim 9, wherein the fault state is to:
indicate that the transistor is in a breakdown mode of operation; and
prevent the temperature-based control circuit from providing a fourth signal to the driver unless the measured temperature is greater than or equal to the fault threshold, the driver to control the transistor responsive to the fourth signal.

12. The method of claim 8, wherein the measured temperature being greater than or equal to the fault threshold indicates that the transistor is in a breakdown mode of operation, and the method includes:
providing the first signal to the driver, the driver to control the transistor responsive to the first signal to dissipate heat; and
responsive to the measured temperature being less than the lower threshold, providing a fourth signal to the driver, the driver to control the transistor responsive to the fourth signal to allow for the transistor to return to the breakdown mode of operation if a voltage across an integrated circuit is at a breakdown level, the transistor packaged in the integrated circuit.

13. The method of claim 8, including providing the first signal to the driver, the driver to control the transistor responsive to the first signal to regulate a voltage across an integrated circuit from a breakdown level to a supply level for the temperature-based control circuit and the driver, the transistor packaged in the integrated circuit.

14. The method of claim 8, wherein the temperature corresponds to a junction temperature of the transistor.

15. A non-transitory computer-readable medium comprising instructions that cause at least one programmable circuit to:
monitor a temperature sensor to determine a measured temperature indicative of a temperature of a transistor;
responsive to the measured temperature being greater than or equal to a fault threshold, provide a first signal to a driver, the driver to control the transistor responsive to the first signal;
responsive to the measured temperature being less than a lower threshold, provide a second signal to the driver, the driver to control the transistor responsive to the second signal; and
responsive to the measured temperature being greater than or equal to an upper threshold, provide a third signal to the driver, the driver to control the transistor responsive to the third signal, the upper threshold being less than the fault threshold.

16. The non-transitory computer-readable medium of claim 15, wherein the instructions cause one or more of the at least one programmable circuit to:
responsive to the measured temperature being greater than or equal to the fault threshold, set a fault state; and
responsive to the measured temperature being less than a cleared fault threshold, clear the fault state, the cleared fault threshold less than the lower threshold.

17. The non-transitory computer-readable medium of claim 16, wherein the instructions cause one or more of the at least one programmable circuit to, responsive to the measured temperature not being greater than or equal to the upper threshold, determine whether the measured temperature is less than the cleared fault threshold.

18. The non-transitory computer-readable medium of claim 16, wherein the fault state is to:
indicate that the transistor is in a breakdown mode of operation; and
prevent one or more of the at least one programmable circuit from providing a fourth signal to the driver unless the measured temperature is greater than or equal to the fault threshold, the driver to control the transistor responsive to the fourth signal.

19. The non-transitory computer-readable medium of claim 15, wherein the measured temperature being greater than or equal to the fault threshold indicates that the transistor is in a breakdown mode of operation, and wherein the instructions cause one or more of the at least one programmable circuit to:
provide the first signal to the driver, the driver to control the transistor responsive to the first signal to dissipate heat; and
responsive to the measured temperature being less than the lower threshold, provide a fourth signal to the driver, the driver to control the transistor responsive to the fourth signal to allow for the transistor to return to the breakdown mode of operation if a voltage across an integrated circuit is at a breakdown level, the transistor packaged in the integrated circuit.

20. The non-transitory computer-readable medium of claim 15, wherein the instructions cause one or more of the at least one programmable circuit to provide the first signal to the driver, the driver to control the transistor responsive to the first signal to regulate a voltage across an integrated circuit from a breakdown level to a supply level for the driver, the transistor packaged in the integrated circuit.
